(19) United States
(12) Patent Application Publication
(10) Pub. No.: US 2018/0327622 A1
(43) Pub. Date: Nov. 15, 2018

(54) PRINTING FORMULATION AND APPLICATION THEREOF

(71) Applicant: GUANGZHOU CHINARAY OPTOELECTRONIC MATERIALS LTD., Guangzhou (CN)

(72) Inventors: Junyou PAN, Guangzhou (CN); Xi YANG, Guangzhou (CN); Xiaolin YAN, Guangzhou (CN)

(21) Appl. No.: 15/775,394

(22) PCT Filed: Sep. 26, 2016
(86) PCT No.: PCT/CN2016/100163

§ 371 Date: May 11, 2018

(30) Foreign Application Priority Data
Nov. 12, 2015 (CN) 201510770142.0

(51) Int. Cl. C09D 11/52; C09D 11/50; C09D 11/36; C09D 11/322; C09D 11/033; C09D 11/037; C09K 11/02; C09K 11/56; C09K 11/88; C09K 11/06; H01L 51/00

(52) U.S. Cl. CPC C09D 11/52; H01L 51/5012; C09D 11/36; C09D 11/322; C09D 11/033; C09D 11/037; C09K 11/025; C09K 11/565; C09K 11/883; C09K 11/06; H01L 51/0007; H01L 51/0072; H01L 51/0067; H01L 51/0085; H01L 51/0058; H01L 51/0056; H01L 51/0059; C09K 2211/185; C09K 2211/1059; C09K 2211/1007; C09K 2211/1014; H01L 51/0004; C09D 11/50

(57) ABSTRACT

Provided are a printing formulation and application in electroluminescent devices thereof, the formulation comprises at least one functional material and at least one solvent formulation containing sulfur, or nitrogen, or phosphorus.

### CROSS-REFERENCE TO RELATED APPLICATIONS

The present application is the national phase of International Application No. PCT/CN2016/100163, filed on Sep. 26, 2016, which claims priority to Chinese Application No. 201510770142.0, filed on Nov. 12, 2015, both of which are incorporated herein by reference in their entireties.

### TECHNICAL FIELD

The present disclosure relates to the technical field of organic electroluminescence, and more particularly, to a printing formulation and the use thereof.

### BACKGROUND

Currently, the organic light-emitting diode (OLED), as a new generation of displays, is manufactured by an evaporation method resulting in a low material utilization, and the method requires a fine metal mask (FMM) that would increase the cost and decrease the yield. In order to solve above problems, a printing technology for realizing a high-resolution full-color display attracts more and more attention. For example, a large-area functional material film can be produced by ink-jet printing at a low cost. The ink-jet printing has great advantages and potential over the traditional semiconductor production processes for its low energy consumption, low water consumption and environmental friendliness. Another new display technology is quantum dot light-emitting diode (QLED), which cannot be produced by an evaporation method, but only can be manufactured by printing. Therefore, in order to achieve a printed display, it is necessary to make a breakthrough in printing inks and solve principal problems of related printing processes. The viscosity and surface tension are important parameters that affect the printing inks and the printing processes. A promising printing ink requires a suitable viscosity and surface tension.

Organic semiconductor materials have gained widespread attention and have made remarkable progress in electronic and optoelectronic devices due to solution processability thereof. The solution processability allows an organic functional material to form a thin film of such functional material in a device through certain coating and printing techniques. Such techniques can effectively reduce the processing costs of electronic and optoelectronic devices and satisfy the need of large-area manufacture. Up to now, a plurality of companies have reported organic semiconductor material printing inks, for example, KATEEVA, INC disclosed an ink comprising a small-molecular organic material based on an ester solvent for printable OLEDs (US2015044802A1); UNIVERSAL DISPLAY CORPORATION disclosed a printable ink comprising a small-molecular organic material based on aromatic ketone or aromatic ether solvents (US20120205637); and SEIKO EPSON CORPORATION disclosed a printable ink comprising an organic polymer material based on substituted benzene derivative solvent. Other examples relating to organic functional material printing inks may be found in CN102408776A, CN103173060A, CN103824959A, CN1180049C, CN102124588B, US2009130296A1 and US2014097406A1.

Another kind of functional material suitable for printing is an inorganic nanomaterial, particularly quantum dots. Quantum dots are a nano-sized semiconductor material with the quantum confinement effect. Under stimulation of light or electricity, the quantum dots can emit fluorescence light of specific energy, and the color (energy) of the fluorescent light depends on the chemical compositions, sizes and shapes of the quantum dots. Therefore, electrical and optical properties of the quantum dots can be effectively regulated by controlling the sizes and shapes of the quantum dots. Currently, countries are conducting research in applications of quantum dots in full-color aspects, mainly in the display field. Recently, electroluminescent devices having quantum dots as a light-emitting layer (QLED) have been rapidly developed and lifetime of such devices has been greatly improved, as reported by Peng et al., Nature Vol 515 96 (2015) and Qian et al., Nature Photonics Vol 9 259 (2015). Currently, several companies have reported on quantum dot inks for printing: Nanoco Technologies Ltd. in the United Kingdom disclosed a method for preparing a printable ink formulation comprising nanoparticles (CN101878535B). By selecting suitable solvents, such as toluene and dodecaneselenol, a printable nanoparticle ink and corresponding nanoparticle-containing film are obtained. Samsung Electronics disclosed a quantum dot ink for ink-jet printing (U.S. Pat. No. 8,765,014B2). The ink comprises a certain concentration of quantum dot materials, organic solvents and high-viscosity alcohol polymer additives. A quantum dot film is fabricated by printing the ink to produce a quantum dot electroluminescent device. QD Vision Inc. disclosed a quantum dot ink formulation, comprising a host material, a quantum dot material and an additive (US2010264371A1).

Other patent documents relating to quantum dot printing inks include US2008277626A1, US2015079720A1, US2015075397A1, TW201340370A, US2007225402A1, US2008169753A1, US2010265307A1, US2015101665A1 and WO2008105792A2. In these published documents, all the quantum dot inks comprise other additional additives, such as, alcohol polymers for regulating physical parameters of the inks. Incorporation of the insulating polymer additives tends to reduce charge-transport ability of film, and negatively affects optoelectric properties of devices, and limits applications of quantum dot inks in the optoelectric devices.

### SUMMARY

An object of the present disclosure is to provide a printing formulation.

Specific technical schemes are described as follows.

A printing formulation comprises a functional material and a solvent formulation, wherein the solvent formulation is one or more selected from compounds of the following formulae:

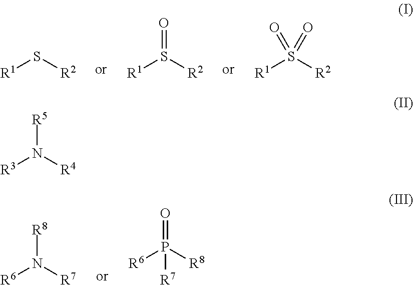

wherein, R¹, R², R³, R⁴, R⁵, R⁶, R⁷ and R⁸ are identical or different and are each independently selected from H; D; straight-chain alkyl, straight-chain alkoxy, or straight-chain thioalkoxy each containing 1-20 C atoms; branched or cyclic alkyl, branched or cyclic alkoxy, branched or cyclic thioalkoxy, or branched or cyclic silyl each containing 3-20 C atoms; substituted C₁-C₂₀ keto; C₂-C₂₀ alkoxycarbonyl; C₇-C₂₀ aryloxycarbonyl, cyano, carbamoyl, haloformyl, formyl, isocyano, an isocyanate group, a thiocyanate group, an isothiocyanate group, hydroxyl, nitro, a CF₃ group, Cl, Br, F; a substituted or unsubstituted 5- to 40-membered aromatic or heteroaromatic ring; or a 5- to 40-membered aryloxy or heteroaryloxy ring.

In some embodiments, the solvent formulation has a viscosity at 25° C. ranged from 1 cPs to 100 cPs and a boiling point of 150° C. or above.

In some embodiments, the solvent formulation has a surface tension at 25° C. ranged from 19 dyne/cm to 50 dyne/cm.

In some embodiments, the functional material accounts for 0.3%-70% based on the total weight of the printing formulation, and the solvent formulation accounts for 30%-990.7% based on the total weight of the printing formulation.

In some embodiments, the solvent formulation is one or more selected from diphenyl sulfide, tert-dodecylthiol, dimethyl sulfoxide, sulfolane, dimethylsulfone, 2,4-dimethylsulfolane, N-benzylmethylamine, triisopentylamine, dihexylamine, trihexylamine, dioctylamine, decylamine, didecylamine, aniline, N-methylaniline, N,N-dimethylaniline, N,N-diethylaniline, N-propylaniline, N-butylaniline, N,N-dibutylaniline, N-pentylaniline, N,N-dipentylaniline, N,N-di-tert-pentylaniline, 3,5-dimethylaniline, benzylamine, o-toluidine, m-toluidine, p-toluidine, 4-tert-pentylaniline, N,N-diethylbenzylamine, N,N-diethylcyclohexylamine, diethylenetriamine, triethylenetetramine, formamide, N-methylformamide, acetamide, N-methylacetamide, 2-pyrollidinone, N-methylpyrollidinone, trihexylphosphine, trioctylphosphine, trimethyl phosphate, triethyl phosphate, triphenyl phosphate, and diethyl phosphate.

In some embodiments, the solvent formulation further comprises a second solvent, and the second solvent is one or more selected from a group consisting of an aromatic compound, a heteroaromatic compound, an ester compound, fatty ketone, or fatty ether. In one embodiment, the second solvent is one or more selected from methanol, ethanol, 2-methoxy ethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, 2-butanone, 1,2-dichloroethane, 3-phenoxyl toluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decahydronaphthalene, or indene.

In some embodiments, the functional material is an inorganic nanomaterial.

In some embodiments, the inorganic nanomaterial is a luminescent quantum dot material which can emit light having a wavelength ranged from 380 nm to 2500 nm.

In some embodiments, the inorganic nanomaterial is selected from binary or multinary semiconductor compounds of Group IV, II-VI, II-V, III-V, III-VI, IV-VI, I-III-VI, II-IV-VI and II-IV-V of the Periodic Table of the Elements or any mixture thereof.

In some embodiments, the inorganic nanomaterial is a metal nanoparticle material, a metal oxide nanoparticle material, or any mixture thereof.

In some embodiments, the inorganic nanomaterial is a perovskite nanoparticle material.

In some embodiments, the functional material is an organic functional material, which is selected from a hole-injection material, a hole-transport material, an electron-transport material, an electron-injection material, an electron-blocking material, a hole-blocking material, a light emitter, a host material or an organic dye.

Another object of the present disclosure is to provide a use of the printing formulation described above.

Specific technical schemes are as follows.

A use of the printing formulation described above in preparation of an electronic device.

Another object of the present disclosure is to provide an electronic device.

Specific technical schemes are described as follows:

An electronic device uses a functional film prepared from the printing formulation described above.

In some embodiments, a method for preparing the functional film includes a step of coating the printing formulation on the substrate.

In some embodiments, the coating method is selected from ink-jet printing, nozzle printing, typographic printing, screen printing, dip coating, spin coating, blade coating, roller printing, torsion roller printing, lithographic printing, flexographic printing, rotary printing, spray coating, brush coating, pad printing, or slot die coating.

In some embodiments, the electronic device is selected from a quantum dot light-emitting diode, a quantum dot photovoltaic cell, a quantum dot light-emitting electrochemical cell, a quantum dot field effect transistor, a quantum dot light-emitting field effect transistor, a quantum dot laser, a quantum dot sensor, an organic light-emitting diode, an organic photovoltaic cell, an organic light-emitting electrochemical cell, an organic field effect transistor, an organic light-emitting field effect transistor, an organic laser and an organic sensor.

The present disclosure provides a formulation suitable for preparing an electronic device by printing, wherein the formulation comprises at least one organic solvent containing sulfur, nitrogen, or phosphorus and at least one functional material, the at least one organic solvent containing sulfur, nitrogen, or phosphorus respectively has a structure represented by general formulae (I) or (II) or (III). In some embodiments, the formulation has a boiling point of 150° C. or above, a viscosity at 25° C. ranged from 1 cPs to 100 cPs, and a surface tension at 25° C. ranged from 19 dyne/cm to 50 dyne/cm. A functional material film with a uniform thickness and a uniform formulation property can be formed from the printing formulation which satisfies the above boiling point, surface tension, and viscosity parameters.

The present disclosure further relates to an electronic device manufactured from the formulation. The printing formulation of the present disclosure is suitable for ink-jet printing and forming a film having a uniform surface by controlling the viscosity disclosure in a range of from 1 cPs to 100 cPs and the surface tension at 25° C. in a range of from 19 dyne/cm to 50 dyne/cm. And the organic solvent can be effectively removed by a post processing, such as, a heat treatment or a vacuum treatment, thereby ensuring properties of the electronic device. Accordingly, the present disclosure provides the printing ink, particularly, the printing ink comprising the quantum dots and the organic semiconductor material, for preparing a high-quality functional material, to provide technical solutions for electronic devices or optoelectronic devices having printable functional materials.

### BRIEF DESCRIPTION OF DRAWINGS

FIG. 1 is a schematic structural view of an organic electroluminescent device according to one embodiment of the present disclosure, wherein 101 is a substrate, 102 is an anode, 103 is a hole-injection layer (HIL) or a hole-transport layer (HTL), 104 is a light-emitting layer (an electroluminescence device) or a light-absorbing layer (a photovoltaic cell), 105 is an electron-injection layer (EIL) or an electron-transport layer (ETL), and 106 is a cathode.

### DETAILED DESCRIPTION

To facilitate understanding of the present disclosure, the present disclosure will be described more fully hereinafter with reference to the accompanying drawings. The embodiments of the present disclosure are given in the accompanying drawings. However, the present disclosure may be embodied in various different forms and is not limited to the embodiments described herein. Instead, these embodiments are provided to achieve more thorough and complete understanding of the present disclosure.

Unless otherwise defined, all technical and scientific terms used herein have the same meaning as commonly understood by those skilled in the art of present disclosure. The terms used in the description of the present disclosure herein are merely to describe specific embodiments and are not intended to limit the present disclosure. As used herein, the term “and/or” includes any and all combinations of one or more of the associated listed items.

The present disclosure provides a printing formulation, comprising at least one organic solvent containing sulfur, nitrogen, or phosphorus and at least one functional material, the at least one organic solvent containing sulfur, nitrogen, or phosphorus respectively has a structure of general formulae (I), (II), or (III). In some embodiments, the organic solvent has a boiling point of 150° C. or above, a viscosity at 25° C. ranged from 1 cPs to 100 cPs, and a surface tension at 25° C. ranged from 19 dyne/cm to 50 dyne/cm. The present disclosure further relates to a printing process of the formulation and a use of the formulation in an electronic device, and particularly to a use in the electroluminescence device. The present disclosure further relates to an electronic device manufactured from the formulation.

In the present disclosure, the terms “printing formulation” and “printing ink”, or “ink” have the same meaning, and are interchangeable.

The present disclosure provides a printing formulation, comprising at least one functional material and at least one organic solvent, the at least one organic solvent has a general structural formula below:

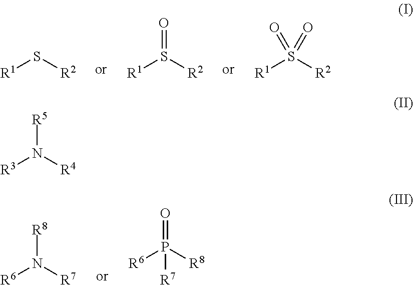

wherein R¹, R², R³, R⁴, R⁵, R⁶, R⁷ and R⁸ may be, identically or differently, H, D or straight-chain alkyl, straight-chain alkoxy or straight-chain thioalkoxy each containing 1-20 C atoms; branched or cyclic alkyl, branched or cyclic alkoxy, branched or cyclic thioalkoxy or branched or cyclic silyl each containing 3-20 C atoms; substituted C₁-C₂₀ keto, C₂-C₂₀ alkoxycarbonyl; C₇-C₂₀ aryloxycarbonyl, cyano (—CN), carbamoyl (—C(═O)NH₂), haloformyl (—C(═O)—X, where X represents a halogen atom), formyl (—C(═O)—H), isocyano, an isocyanate group, a thiocyanate group, an isothiocyanate group, hydroxyl, nitro, a CF₃ group, Cl, Br, F, a crosslinkable group; a substituted or unsubstituted 5- to 40-membered aromatic or heteroaromatic ring, or a 5- to 40-membered aryloxy or heteroaryloxy ring, or any combination thereof. One or more of R¹ and R² in the formula (I), one or more of R³, R⁴ and R⁵ in the formula (II), and one or more of R⁶, R⁷ and R⁸ in the formula (III) may form a monocyclic or a polycyclic aliphatic or aromatic ring system with each other, and/or with a ring boned to the groups.

The at least one organic solvent has a boiling point of 150° C. or above and can be evaporated from solvent systems to form film of functional materials.

In some embodiments, R¹, R², R³, R⁴, R⁵, R⁶, R⁷ and R⁸ may be, identically or differently, H, D or straight-chain alkyl, straight-chain alkoxy or straight-chain thioalkoxy each containing 1-10 C atoms; branched or cyclic alkyl, branched or cyclic alkoxy, branched or cyclic thioalkoxy or branched or cyclic silyl each containing 3-10 C atoms; substituted C₁-C₁₀ keto, C₂-C₁₀ alkoxycarbonyl; C₇-C₁₀ aryloxycarbonyl, cyano (—CN), carbamoyl (—C(═O)NH₂), haloformyl (—C(═O)—X, where X represents a halogen atom), formyl (—C(═O)—H), isocyano, an isocyanate group, a thiocyanate group or an isothiocyanate group, hydroxyl, nitro, a CF₃ group, Cl, Br, F, a crosslinkable group; a substituted or unsubstituted 5- to 20-membered aromatic or heteroaromatic ring, or a 5- to 20-membered aryloxy or heteroaryloxy ring, or any combination thereof. One or more of R¹ and R² in the formula (I), one or more of R³, R⁴ and R⁵ in the formula (II), and one or more of R⁶, R⁷ and R⁸ in the formula (III) may form a monocyclic or a polycyclic aliphatic or aromatic ring system with each other, and/or with a ring boned to the groups.

In some embodiments, the at least one organic solvent has a boiling point of 150° C. or above. In some embodiments, the at least one organic solvent has a boiling point of 180° C. or above. In some embodiments, the at least one organic solvent has a boiling point of 200° C. or above. In other embodiments, the at least one organic solvent has a boiling point of 250° C. or above, or 300° C. or above. When the boiling point is within the above ranges, it is beneficial to prevent a nozzle from being clogged. The at least one organic solvent can be evaporated from the solvent system thereby forming a film having the functional material.

In some embodiments, the at least one organic solvent in the formulation of the present disclosure has a viscosity at 25° C. ranged from 1 cPs to 100 cPs.

The viscosity can be adjusted by different methods, for example, by selecting a suitable organic solvent and a concentration of the functional material in the formulation. The solvent system comprising at least one organic solvent of the present disclosure can facilitate adjusting the printing ink within a suitable range according to a printing method as used. Typically, the functional material in the formulation of the present disclosure has a weight ratio within a range of 0.3-30 wt %, in one embodiment, the functional material in the formulation of the present disclosure has a weight ratio within a range of 0.5-20 wt %, in another embodiment, the functional material in the formulation of the present disclosure has a weight ratio within a range of 0.5-15 wt %, and in yet another embodiment, the functional material in the formulation of the present disclosure has a weight ratio within a range of 0.5-10 wt %. The viscosity of the at least one organic solvent can be less than 100 cps, in one embodiment less than 50 cps, and in another embodiment ranged from 1.5 cps to 20 cps.

In one embodiment, the viscosity at 25° C. of the formulation of the present disclosure formulated according to the above ratios is ranged from 1 cps-100 cps, in another embodiment, the viscosity at 25° C. of the formulation of the present disclosure formulated according to the above ratios is ranged from 1 cps to 50 cps, and in yet another embodiment, the viscosity at 25° C. of the formulation of the present disclosure formulated according to the above ratios is ranged from 1.5 cps to 20 cps. The viscosity herein refers to a viscosity at ambient temperature during printing, and ranged, typically, from 15° C. to 30° C., in one embodiment from 18° C. to 28° C., in another embodiment from 20° C. to 25° C., and in yet another embodiment from 23 to 25° C. Such formulated formulation is especially suitable for the ink-jet printing.

The at least one organic solvent in the formulation of the present disclosure has a surface tension at 25° C. ranged from 19 dyne/cm to 50 dyne/cm.

A suitable surface tension parameter of the formulation is suitable for a particular substrate and a particular printing method. For example, regarding the ink-jet printing, the surface tension of the at least one organic solvent at 25° C. is ranged from about 19 dyne/cm to 50 dyne/cm. In one more embodiment, the surface tension of the at least one organic solvent at 25° C. is ranged from about 22 dyne/cm to 35 dyne/cm. In one embodiment, the surface tension of the at least one organic solvent at 25° C. is ranged from about 25 dyne/cm to 33 dyne/cm.

In one embodiment, the surface tension of the formulation of the present disclosure at 25° C. is ranged from about 19 dyne/cm to 50 dyne/cm, in another embodiment, the surface tension of the formulation of the present disclosure at 25° C. is ranged from 22 dyne/cm to 35 dyne/cm, in yet another embodiment, the surface tension of the formulation of the present disclosure at 25° C. is ranged from 25 dyne/cm to 33 dyne/cm. Such formulated formulation is particularly suitable for the ink-j et printing.

A functional material film having a uniform thickness and uniform formulation property can be formed from the formulation based on a solvent system of the at least one organic solvent, which satisfies the above boiling point, surface tension and viscosity parameter.

In some embodiments, the at least one organic solvent in the formulation of the present disclosure has a structure represented by any of the above formulae (I) or (II) or (III), wherein at least one of R¹-R², R³-R⁵ and R⁶-R⁸ in the formulae is a fatty chain.

In some embodiments, the at least one organic solvent in the formulation of the present disclosure has a structure represented by the above formula (I) or (II) or (III), wherein at least one of R¹-R², R³-R⁵ and R⁶-R⁸ in the formulae is an aromatic or heteroaromatic group.

An aromatic group refers to a hydrocarbyl group having at least one aromatic ring, which can be a monocylic group or a polycyclic ring system. A heteroaromatic group refers to a hydrocarbyl group having at least one heteroaromatic ring (containing a heteroatom), which can be a monocylic group and polycyclic ring system. These polycyclic rings may have two or more rings, among which two adjacent rings share two carbon atoms to form a fused ring. At least one of the polycyclic rings is an aromatic or heteroaromatic ring.

Specifically, examples of an aromatic group include benzene, naphthalene, anthracene, phenanthrene, perylene, tetracene, pyrene, benzopyrene, triphenylene, acenaphthene, fluorene and derivatives thereof.

Specifically, examples of a heteroaromatic group include furan, benzofuran, thiophene, benzothiophene, pyrrole, pyrazole, triazole, imidazole, oxazole, oxadiazole, thiazole, tetrazole, indole, carbazole, pyrroloimidazole, pyrrolopyrrole, thienopyrrole, thienothiophene, furopyrrole, furofuran, thienofuran, benzisoxazole, benzisothiazole, benzimidazole, pyridine, pyrazine, pyridazine, pyrimidine, triazine, quinoline, isoquinoline, phthalazine, cinnoline, quinoxaline, phenanthridine, perimidine, quinazoline, quinazolinone and derivatives thereof.

In some embodiments, the at least one organic solvent of formula (I) in the formulation of the present disclosure is selected from (but not limited to) following compounds containing sulfur: diphenyl sulfide, tert-dodecylthiol, dimethyl sulfoxide, sulfolane and dimethylsulfone and 2,4-dimethylsulfolane.

In other embodiments, the at least one organic solvent of formula (II) in the formulation of the present disclosure is selected from (but not limited to) following compounds containing nitrogen: N-benzylmethylamine, triisopentylamine, dihexylamine, trihexylamine, dioctylamine, decylamine, didecylamine, aniline, N-methylaniline, N,N-dimethylaniline, N,N-diethylaniline, N-propylaniline, N-butylaniline, N,N-dibutylaniline, N-pentylaniline, N,N-dipentylaniline, N,N-di-tert-pentylaniline, 3,5-dimethylaniline, benzylamine, o-toluidine, m-toluidine, p-toluidine, 4-tert-pentylaniline, N,N-diethylbenzylamine, N,N-diethylcyclohexylamine, diethylenetriamine, triethylenetetramine, formamide, N-methylformamide, acetamide, N-methylacetamide, 2-pyrollidinone and N-methylpyrollidinone.

In some embodiments, the at least one organic solvent of the formula (III) in the formulation of the present disclosure is selected from (but not limited to) following compounds containing phorphous: trihexylphosphine, trioctylphosphine, trimethyl phosphate, triethyl phosphate, triphenyl phosphate and diethyl phosphate.

The formulation of the present disclosure comprises at least one other organic solvent, the at least one other organic solvent is selected from an organic solvent having a structure of any of the formulae (I) or (II) or (III), or other organic solvents.

In some embodiments, the organic solvent having a structure represented by any of the above formulae (I), (II), or (III) described in the present disclosure accounts for 50% or more, in one embodiment, accounts for 70% or more, in another embodiment, accounts for 90% or more by weight of the mixed solvents.

In some embodiments, the at least one other solvent in the formulation of the present disclosure is selected from an aromatic compound, a heteroaromatic compound, an ester compound, fatty ketone, aromatic ketone, aromatic ether, or fatty ether.

In other embodiments, examples of the at least one other solvent (the second solvent) in the printing formulation of the present disclosure include (but not limited to) methanol, ethanol, 2-methoxy ethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, 2-butanone, 1,2-dichloroethane, 3-phenoxyl toluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decahydronaphthalene, indene and/or any mixture thereof.

The system of the solvents having formula (I) or (II) or (III) can effectively dispersing the functional material, e.g., as a new dispersing solvent to replace traditional solvents for dispersing the functional material, such as, toluene, xylene, chloroform, chlorobenzene, dichlorobenzene and n-heptane.

Listed below are the boiling point, surface tension, and viscosity parameters of some of the above described solvents having the formulae (I) or (II) or (III):

| | | | Surface | |
|---|---|---|---|---|
| | | Boiling | Tension@RT | Viscosity@RT |
| Name | Structural Formula | Point(° C.) | (dyne/cm) | (cPs) |
| diphenyl sulfide | 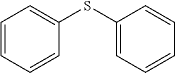 [SMILES: c1ccc(Sc2ccccc2)cc1] | 296 | 46 | N.N. |
| tert-dodecylthiol | CH₃(CH₂)₁₀(SH)CH₃ | 227 | 27 | 3.36 |
| dimethyl sulfoxide | 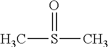 | 189 | 42 | 2 |
| sulfolane | 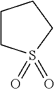 | 287 | 35 | 10 |
| 2,4-dimethylsulfolane | 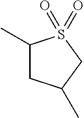 | 280 | 28 | 7.9 |
| aniline | 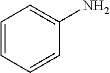 | 185 | 42 | 4.5 |
| N-methyl aniline | 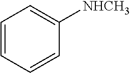 | 196 | 40 | 2.5 |
| N,N-dimethylaniline | 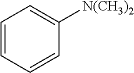 | 193 | 36 | 1.5 |
| N,N-diethylaniline | 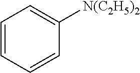 | 217 | 34 | 2 |
| N-butylaniline | 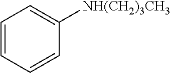 | 241 | 34 | 3.2 |
| N,N-dibutylaniline | 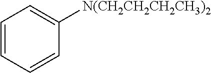 | 274 | 32 | 6.8 |
| o-toluidine | 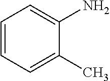 | 200 | 40 | 3.4 |
| m-toluidine | 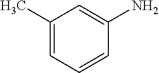 | 203 | 38 | 4.4 |
| p-toluidine | 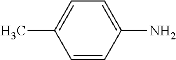 | 200 | 36 | 2 |
| diethylenetriamine | H₂NCH₂CH₂NHCH₂CH₂NH₂ | 206 | 39 | 7.1 |
| N-methylformamide | 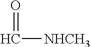 | 185 | 38 | 1.7 |
| N-methylacetamide | 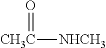 | 206 | 34 | 3.2 |
| 2-pyrollidinone | 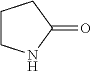 | 245 | 47 | 13 |
| N-methylpyrollidinone | 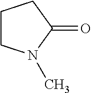 | 204 | 41 | 1.65 |
| triphenyl phosphate | 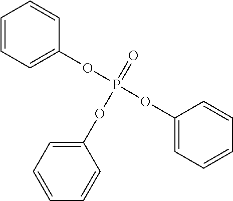 [SMILES: O=P(Oc1ccccc1)(Oc1ccccc1)Oc1ccccc1] | 245 | 40 | 11 |

The printing ink may also further comprise one or more components, such as, a surfactant, a lubricant, a wetting agent, a dispersant, a hydrophobing agent, a binder, for adjusting the viscosity and film-forming property, and improving adhesion, etc.

A functional film can be formed by depositing the printing ink by various techniques, wherein suitable printing or coating techniques include (but are not limited to) ink-jet printing, nozzle printing, typographic printing, screenprinting, dip coating, spin coating, blade coating, roller printing, torsion roller printing, lithographic printing, flexographic printing, rotary printing, spray coating, brush coating or pad printing, and slot die coating. Photogravure printing, spray printing and ink-jet printing are preferred. For detailed information about printing techniques and related requirements on solvents, concentrations, and viscosities and the like of the ink, please refer to Handbook of Print Media: Technologies and Production Methods), ISBN 3-540-67326-1 edited by Helmut Kipphan. Typically, different printing techniques have different requirements on properties of inks employed. For example, regarding the printing ink suitable for ink-jet printing, it is required to adjust the surface tension, viscosity, and wettability of the ink so that the ink can be smoothly jetted through a nozzle at a printing temperature (such as, room temperature, 25° C.) without being dried in the nozzles or clogging the nozzles, or it can form a continuous, complete and defect-free film on a specific substrate.

The printing formulation of the present disclosure comprises at least one functional material.

In the present disclosure, a functional material can be a material having an optoelectronic function. The optoelectronic functions include, but are not limited to, hole injection function, hole transport function, electron-transport function, electron-injection function, electron-blocking function, hole-blocking function, light-emitting function and host function. Corresponding functional materials are referred to as a hole-injection material (HIM), a hole-transport material (HTM), an electron-transport material (ETM), an electron-injection material (EIM), an electron-blocking material (EBM), a hole-blocking material (HBM), a light emitter (Emitter) and a host material (Host).

The functional material can be an organic material or an inorganic material.

In one embodiment, the at least one functional material in the formulation of the present disclosure is an inorganic nanomaterial.

In one embodiment, the at least one inorganic nanomaterial in the formulation is an inorganic semiconductor nanoparticle material.

In the present disclosure, an average particle size of the inorganic nanomaterial is ranged from about 1 nm to about 1000 nm. In some embodiments, an average particle size of the inorganic nanomaterial is ranged from about 1 to about 100 nm. In some more embodiments, an average particle size of the inorganic nanomaterial is ranged from about 1 to about 20 nm, and in one embodiment, from 1 to 10 nm.

The inorganic nanomaterial can have different shapes, including but not limited to a spherical nano-morphology, a cubic nano-morphology, a rodlike nano-morphology, a disk nano-morphology, a branched structure nano-morphology, or a combination thereof.

In one embodiment, the inorganic nanomaterial is a quantum dot material having a very narrow monodispersed size distribution, in other words, a difference in sizes between particles is very small. In some embodiment, a root-mean-square deviation of sizes of monodispersed quantum dots is less than 15% rms, in one embodiment, less than 10% rms, and in yet another embodiment, less than 5% rms.

In one embodiment, the inorganic nanomaterial is a luminescent material.

In one more embodiment, the luminescent inorganic nanomaterial is a luminescent quantum dot material.

Typically, luminescent quantum dots can emit light having a wavelength ranged from 380 nm to 2500 nm. For example, it is found that a wavelength of light emitted from the quantum dot having a CdS core is ranged from about 400 nm to about 560 nm; a wavelength of light emitted from the quantum dot having a CdSe core is ranged from about 490 nm to about 620 nm; a wavelength of light emitted from the quantum dot having a CdTe core is ranged from about 620 nm to about 680 nm; a wavelength of light emitted from the quantum dot having a InGaP core is ranged from about 600 nm to about 700 nm; a wavelength of light emitted from the quantum dot having a PbS core is ranged from about 800 nm to about 2500 nm; a wavelength of light emitted from quantum dot having a PbSe core is ranged from about 1200 nm to about 2500 nm; a wavelength of the light emitted from quantum dot having a CuInGaS core is ranged from about 600 nm to about 680 nm; a wavelength of light emitted from the quantum dot having a ZnCuInGaS core is ranged from about 500 nm to about 620 nm; and a wavelength of light emitted from the quantum dot having a CuInGaSe core is ranged from about 700 nm to about 1000 nm.

In one embodiment, the quantum dot material comprises at least one material capable of emitting blue light having an emission peak wavelength ranged from 450 nm to 460 nm, or green light having an emission peak wavelength ranged from 520 nm to 540 nm, or red light having an emission peak wavelength ranged from 615 nm to 630 nm, or any mixture thereof.

The quantum dots may be selected as having special chemical compositions, morphological structures, and/or sizes, so as to emit light having a desired wavelength under electrostimulation. With respect to the relationship between the luminescent properties and the chemical compositions, the morphological structures and/or the sizes of quantum dots, please refer to Annual Review of Material Sci., 2000, 30, 545-610; Optical Materials Express, 2012, 2, 594-628; Nano Res, 2009, 2, 425-447, the entire contents of which are incorporated herein by reference.

A narrow particle size distribution of the quantum dots can make that the quantum dots have a narrower luminescent spectrum (J. Am. Chem. Soc., 1993, 115, 8706; US 20150108405). In addition, the sizes of quantum dots can be correspondingly adjusted within the above-described size ranges according to the chemical composition and structure of the quantum dots, so as to obtain the desired wavelengths.

In one embodiment, the luminescent quantum dots are semiconductor nanocrystals. Typically, a particle size of the semiconductor nanocrystals ranges from about 2 nm to about 15 nm. Further, the sizes of quantum dots can be correspondingly adjusted within the above-described size ranges according to the chemical composition and the structure of the quantum dots, so as to obtain the desired wavelengths.

The semiconductor nanocrystals include at least one semiconductor material, and the semiconductor material can be selected from binary or multinary semiconductor compounds of Group IV, II-VI, II-V, III-V, III-VI, IV-VI, I-III-VI, II-IV-VI and II-IV-V of the Periodic Table of the Elements, or any mixture thereof. Specific examples of the semiconductor material include, but are not limited to semiconductor compounds of Group IV, for example, including elementary substance Si, Ge and binary compounds SiC and SiGe; semiconductor compounds of Group II-VI, including binary compounds (such as, CdSe, CdTe, CdO, CdS, CdSe, ZnS, ZnSe, ZnTe, ZnO, HgO, HgS, HgSe and HgTe), ternary compounds (such as, CdSeS, CdSeTe, CdSTe, CdZnS, CdZnSe, CdZnTe, CgHgS, CdHgSe, ZnSeS, ZnSeTe, ZnSTe, HgSeS, HgSeTe, HgSTe, HgZnS and HgSeSe) and quaternary compounds (such as, CgHgSeS, CdHgSeTe, CgHgSTe, CdZnSeS, CdZnSeTe, HgZnSeTe, HgZnSTe, CdZnSTe and HgZnSeS); semiconductor compounds of Group III-V, including binary compounds (such as, AN, AlP, AlAs, AlSb, GaN, GaP, GaAs, GaSb, InN, InP, InAs and InSb), ternary compounds (such as, AlNP, AlNAs, AlNSb, AlPAs, AlPSb, GaNP, GaNAs, GaNSb, GaPAs, GaPSb, InNP, InNAs, InNSb, InPAs and InPSb), and quaternary compounds (such as, GaAlNAs, GaAlNSb, GaAlPAs, GaInNP, GaInNAs, GaInNSb, GaInPAs, GaInPSb, InAlNP, InAlNAs, InAlNSb, InAlPAs and InAlPSb); semiconductor compounds of Group IV-VI, including binary compounds (such as, SnS, SnSe, SnTe, PbSe, PbS and PbTe), ternary compounds (such as, SnSeS, SnSeTe, SnSTe, SnPbS, SnPbSe, SnPbTe, PbSTe, PbSeS and PbSeTe) and quatemary compounds (such as, SnPbSSe, SnPbSeTe and SnPbSTe).

In one embodiment, the luminescent quantum dots comprise a semiconductor material of Group II-VI, can be selected from CdSe, CdS, CdTe, ZnO, ZnSe, ZnS, ZnTe, HgS, HgSe, HgTe, CdZnSe and any combination thereof. In a suitable embodiment, CdSe and CdS are used as the luminescent quantum dots for visible light since the synthesis processes thereof are relatively developed well.

In another embodiment, the luminescent quantum dots comprise a semiconductor material of Group III-V, can be selected from InAs, InP, InN, GaN, InSb, InAsP, InGaAs, GaAs, GaP, GaSb, AlP, AlN, AlAs, AlSb, CdSeTe, ZnCdSe and any combination thereof.

In another embodiment, the luminescent quantum dots comprise a semiconductor material of Group IV-VI, can be selected from PbSe, PbTe, PbS, PbSnTe, Tl₂SnTe₅ and any combination thereof.

In one embodiment, a quantum dot has a core-shell structure. The core and shell, each identically or differently, comprise one or more semiconductor materials.

The core of the quantum dot can be selected from binary or multinary semiconductor compounds of Group IV, II-VI, II-V, III-V, III-VI, IV-VI, I-III-VI, II-IV-VI and II-IV-V of the above Periodic Table of the Elements as described above. Specific examples for the core of the quantum dot include, but are not limited to ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AN, AlP, AlSb, PbO, PbS, PbSe, PbTe, Ge, Si, and any alloy or mixture thereof.

The shell of the quantum dot comprises a semiconductor material identical to or different from that of the core. The semiconductor material usable as the shell can be selected from binary or multinary semiconductor compounds of Group IV, II-VI, II-V, III-V, III-VI, IV-VI, I-III-VI, II-IV-VI and II-IV-V of the Periodic Table of the Elements. Specific examples for the shell of the quantum dot shell include, but are not limited to ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, Si, or any alloy or mixture thereof.

The shell of the core-shell quantum dot can comprise a single layer or a plurality of layers. The shell comprises one or more semiconductor materials identical to or different from those for the core. In one embodiment, the shell has a thickness from about 1 to about 20 layers. In one more embodiment, the shell has a thickness from about 5 to about 10 layers. In some embodiments, the surface of the quantum dot core has two or more shells grown thereon.

In one embodiment, the semiconductor material for the shell has a bandgap larger than that for the core. In one embodiment, the core-shell have a type I heterojunction.

In another embodiment, the semiconductor material for the shell has a bandgap smaller than that for the core.

In one embodiment, the semiconductor material for the shell has an atomic crystal structure identical to or similar to that for the core. This selection is advantageous to reduce stress between the core and the shell, thereby making the quantum dot more stable.

Suitable examples of the core-shell luminescent quantum dots include (but not limited to):

for emitting red light: CdSe/CdS, CdSe/CdS/ZnS, CdSe/CdZnS, etc.;

for emitting green light: CdZnSe/CdZnS, CdSe/ZnS, etc.;

for emitting blue light: CdS/CdZnS, CdZnS/ZnS, etc.

A method for preparing quantum dots is a colloid growth method. In one embodiment, a method for preparing monodispersed quantum dots is selected from hot-injection and/or heating-up. These preparation methods are disclosed in the document: Nano Res, 2009, 2, 425-447; Chem. Mater., 2015, 27 (7), pp 2246-2285, the entire contents of which are incorporated herein by reference.

In one embodiment, the surface of the quantum dot contains an organic ligand. The organic ligand can be used to control the growth process, regulate morphology and reduce defects in the surface of the quantum dot, thereby improving the light-emitting efficiency and stability of the quantum dot. The organic ligand can be selected from the group consisting of pyridine, pyrimidine, furan, amine, alkyl phosphine, alkyl phosphine oxide, alkyl phosphonic acid or alkyl phosphinic acid, alkyl thiol, and the like. Examples of specific organic ligands include but are not limited to tri-n-octylphosphine, tri-n-octylphosphine oxide, trihydroxypropylphosphine, tributylphosphine, tri(dodecyl)phosphine, dibutyl phosphite, tributyl phosphite, octadecyl phosphite, trilauryl phosphite, tridodecyl phosphite, triisodecyl phosphite, bis(2-ethylhexyl)phosphate, tri(tridecyl)phosphate, hexadecylamine, oleylamine, octadecylamine, dioctadecylamine, trioctadecylamine, bis(2-ethylhexyl)amine, octylamine, dioctylamine, trioctyl amine, dodecylamine, didodecylamine, tridodecylamine, hexadecylamine, phenylphosphoric acid, hexylphosphonic acid, tetradecylphosphonic acid, octylphosphonic acid, n-octadecylphosphonic acid, propylene diphosphonic acid, dioctyl ether, diphenyl ether, octanethiol, and dodecanethiol.

In another embodiment, the surface of the quantum dot contains an inorganic ligand. The quantum dot protected by the inorganic ligand can be obtained through ligand exchange with the organic ligand on the surface of a quantum dot. Specific examples of the inorganic ligand include, but are not limited to, S²⁻, HS⁻, Se²⁻, HSe⁻, Te²⁻, HTe⁻, TeS₃^{2-,} OH⁻, NH₂⁻, PO₄³⁻ and MoO₄²⁻. For examples of such inorganic ligands for the quantum dot, please refer to document: J. Am. Chem. Soc. 2011, 133, 10612-10620; ACS Nano, 2014, 9, 9388-9402, the entire contents of which are incorporated herein by reference.

In some embodiments, the surface of the quantum dot has one or more same or different ligands.

In one embodiment, the luminescent spectrum of the monodispersed quantum dots has a symmetrical peak form and a narrow full width at half maximum (FWHM). Typically, the better monodispersity of the quantum dots, the more symmetrical the luminescent peak thereof, and the narrower the FWHM. The FWHM of the luminescent spectrum of the quantum dots can be smaller than 70 nm in one embodiment, smaller than 40 nm in another embodiment, and smaller than 30 nm in yet another embodiment.

Typically, the light-emitting quantum efficiency of the quantum dots is larger than 10%, larger than 50% or more in one embodiment, larger than 60% in another embodiment, and larger than 70% in yet another embodiment.

Other information about materials, techniques, methods, applications of quantum dots which may be useful to the present disclosure is described in the following patent documents: WO2007/117698, WO2007/120877, WO2008/108798, WO2008/105792, WO2008/111947, WO2007/092606, WO2007/117672, WO2008/033388, WO2008/085210, WO2008/13366, WO2008/063652, WO2008/063653, WO2007/143197, WO2008/070028, WO2008/063653, U.S. Pat. No. 6,207,229, U.S. Pat. No. 6,251,303, U.S. Pat. No. 6,319,426, U.S. Pat. No. 6,426,513, U.S. Pat. No. 6,576,291, U.S. Pat. No. 6,607,829, U.S. Pat. No. 6,861,155, U.S. Pat. No. 6,921,496, U.S. Pat. No. 7,060,243, U.S. Pat. No. 7,125,605, U.S. Pat. No. 7,138,098, U.S. Pat. No. 7,150,910, U.S. Pat. No. 7,470,379, U.S. Pat. No. 7,566,476 and WO2006134599A1, the entire contents of which are incorporated herein by reference.

In another embodiment, luminescent semiconductor nanocrystals are nanorods, characteristics of which are different from those of spheric nanocrystal grains. For example, the nanorods emit light polarized axially in the length direction, while the spherical crystal grains emit unpolarized light (referring to Woggon et al., Nano Lett., 2003, 3, p 509). Nanorods has an excellent optical gain property so that they may be used as a laser gain material (referring to Banin et al., Adv. Mater. 2002, 14, p 317). In addition, luminescence of the nanorods can be reversibly switched on and off under control of an external electric field (referring to Banin, et al., Nano Lett. 2005, 5, p 1581). Theses characteristics of nanorods can be incorporated in the device of the present disclosure in certain cases. Examples of preparation of semiconductor nanorods can be found in WO03097904A1, US2008188063A1, US2009053522A1 and KR20050121443A, the entire contents of which are incorporated herein by reference.

In other embodiments, the inorganic nanomaterial in the formulation of the present disclosure is a perovskite nanoparticle material, particularly a luminescent perovskite nanoparticle material.

The perovskite nanoparticle material has a general structural formula of AMX₃, wherein A can be selected from organic amine or alkali metal cation, M can be selected from metal cation, X can be selected from oxygen or halogen anion. Specific examples include, but are not limited to, CsPbCl₃, CsPb(Cl/Br)₃, CsPbBr₃, CsPb(I/Br)₃, CsPbI₃, CH₃NH₃PbCl₃, CH₃NH₃Pb (Cl/Br)₃, CH₃NH₃PbBr₃, CH₃NH₃Pb (I/Br)₃ and CH₃NH₃PbI₃. Documents relating to perovskite nanoparticle materials include Nano Lett., 2015, 15, 3692-3696; ACS Nano, 2015, 9, 4533-4542; Angewandte Chemie, 2015, 127 (19): 5785-5788; Nano Lett., 2015, 15 (4), pp 2640-2644; Adv. Optical Mater. 2014, 2, 670-678; The Journal of Physical Chemistry Letters, 2015, 6 (3): 446-450; J. Mater. Chem. A, 2015, 3, 9187-9193; Inorg. Chem. 2015, 54, 740-745; RSC Adv., 2014, 4, 55908-55911; J. Am. Chem. Soc., 2014, 136 (3), pp 850-853; Part. Part. Syst. Charact. 2015, doi: 10.1002/ppsc. 201400214; Nanoscale, 2013, 5 (19): 8752-8780, the entire contents of which are incorporated herein by reference.

In another embodiment, the inorganic nanomaterial in the formulation of the present disclosure is a metal nanoparticle material, such as a luminescent metal nanoparticle material.

The metal nanoparticles include, but are not limited to, nanoparticles of chrome (Cr), molybdenum (Mo), tungsten (W), rubidium (Ru), rhodium (Rh), nickel (Ni), silver (Ag), copper (Cu), zinc (Zn), palladium (Pd), gold (Au), osmium (Os), rhenium (Re), iridium (Ir) and platinum (Pt). With respect to types, morphologies and synthesis methods of common metal nanoparticles, please refer to Angew. Chem. Int. Ed. 2009, 48, 60-103; Angew. Chem. Int. Ed. 2012, 51, 7656-7673; Adv. Mater. 2003, 15, No. 5, 353-389; Adv. Mater. 2010, 22, 1781-1804; Small. 2008, 3, 310-325; Angew. Chem. Int. Ed. 2008, 47, 2-46 and references cited herein, the entire contents of which are incorporated herein by reference.

In another embodiment, the inorganic nanomaterial has a charge-transport function.

In one embodiment, the inorganic nanomaterial has electron-transport ability. In one embodiment, such inorganic nanomaterial is a n-type semiconductor material. Examples of n-type inorganic semiconductor materials includes, but are not limited to, metal chalcogenides, metal pnictides, or elemental semiconductors, such as, metal oxide, metal sulfide, metal selenide, metal telluride, metal nitride, metal phosphide, or metal arsenide. Some n-type inorganic semiconductor materials are selected from ZnO, ZnS, ZnSe, TiO₂, ZnTe, GaN, GaP, AlN, CdSe, CdS, CdTe, CdZnSe and any combination thereof.

In some embodiments, the inorganic nanomaterial has a hole-transport ability. In one embodiment, such inorganic nanomaterial is a p-type semiconductor material. The p-type inorganic semiconductor material can be selected from NiOₓ, WOₓ, MoOₓ, RuOₓ, VOₓ, CuOₓ and any combination thereof.

In some embodiments, the printing ink of the present disclosure comprises at least two or more inorganic nanomaterials.

In another embodiment, the formulation of the present disclosure comprises at least one organic functional material.

The organic functional materials include, but are not limited to, a hole (electric hole)-injection or hole-transport material (HIM/HTM), a hole-blocking material (HBM), an electron-injection or electron-transport material (EIM/ETM), an electron-blocking material (EBM), an organic host material (Host), a singlet emitter (fluorescence emitter), a thermally activated delayed fluorescence material (TADF), a triplet emitter (phosphorescent emitter), particularly a luminescent organic metal complex, an organic dye. For example, various organic functional materials are described in details in WO2010135519A1, US20090134784A1 and WO2011110277A1, the entire contents of which are incorporated herein by reference.

Typically, a solubility of the organic functional material in the organic solvent of the present disclosure is at least 0.2 wt %, in some embodiment is at least 0.3 wt %, in one embodiment is at least 0.6 wt %, in another embodiment is at least 1.0 wt %, and in yet another embodiment is at least 1.5 wt %.

The organic functional material can be a small-molecular material or a polymer material. In the present disclosure, the small-molecular organic material refers to a material with a molecular weight of not greater than 4000 g/mol, a material with a molecular weight greater than 4000 g/mol is collectively referred as a polymer.

In one embodiment, the functional material in the formulation of the present disclosure is the small-molecular organic material.

In some embodiments, the organic functional material in the formulation of the present disclosure comprises at least one host material and at least one light emitter.

In one embodiment, the organic functional material comprises one host material and one singlet emitter.

In another embodiment, the organic functional material comprises one host material and one triplet emitter.

In another embodiment, the organic functional material comprises one host material and one thermally activated delayed fluorescence material.

In some embodiments, the organic functional material comprises one hole-transport material (HTM), and in one embodiment, the HTM contains a crosslinkable group.

Suitable small-molecular organic functional materials in some embodiments are described in more details below (but are not limited thereto).

1. HIM/HTM/EBM

Suitable organic HIM/HTM materials optionally include compounds having following structural units: phthalocyanine, porphyrin, amine, aromatic amine, biphenyl triarylamine, thiophene, fused thiophene, pyrrole, aniline, carbazole, indolocarbazole and derivatives thereof. Further, a suitable HIM also includes a polymer containing fluorocarbon, a polymer containing a conductive dopant, a conductive polymer, such as PEDOT: PSS.

An electron-blocking layer (EBL) is used to block electrons from an adjacent functional layer, particularly from a light-emitting layer. As compared with a light-emitting device without a blocking layer, the presence of EBL typically improves the light-emitting efficiency. An electron-blocking material (EBM) of an electron-blocking layer (EBL) requires higher LUMO than an adjacent functional layer, such as, a light-emitting layer. In one embodiment, a HBM has a higher energy level of excited state (such as, singlet or triplet, depending on light emitter) than an adjacent light-emitting layer. EBM further has hole-transport function. Generally, an HIM/HTM material having a higher LUMO energy level can be used as EBM.

Examples of cyclic aromatic amine derivative compounds which can be used as HIM, HTM or EBM include (but are not limited to) following general structures:

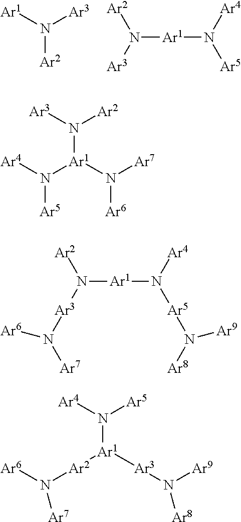

Each of Ar¹-Ar⁹ can be each independently selected from cyclic aromatic hydrocarbon compounds (such as, benzene, biphenyl, triphenyl, benzo, naphthalene, anthracene, phenalene, phenanthrene, fluorene, pyrene, chrysene, perylene, azulene), heterocyclic aromatic compounds (such as, dibenzothiophene, dibenzofuran, furan, thiophene, benzofuran, benzothiophene, carbazole, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indolizine, benzoxazole, benzisoxazole, benzothiazole, quinoline, isoquinoline, phthalazine cinnoline, quinazoline, quinoxaline, naphthalene, phthalein, pteridine, xanthene, acridine, phenazine, phenothiazine, phenoxazine, dibenzoselenophene, benzoselenophene, benzofuropyridine, indolocarbazole, pyridylindole, pyrrolodipyridine, furodipyridine, benzothienopyridine, thienopyridine, benzoselenophenopyridine and selenophenodipyridine); or containing groups having 2-10 rings, these groups can be, identically or differently, cyclic aromatic hydrocarbon groups or heterocyclic aromatic groups and bonded to each other directly or through at least one of following groups: an oxygen atom, a nitrogen atom, a sulfur atom, a silicon atom, a phosphorous atom, a boron atom, a chain structural unit, and a cyclic aliphatic group. Each Ar can be further substituted by a substituent, which can be selected from hydrogen, alkyl, alkoxy, amino, alkenyl, alkynyl, aralkyl, heteroalkyl, aryl and heteroaryl.

In one aspect, Ar¹ to Ar⁹ can be independently selected from following groups:

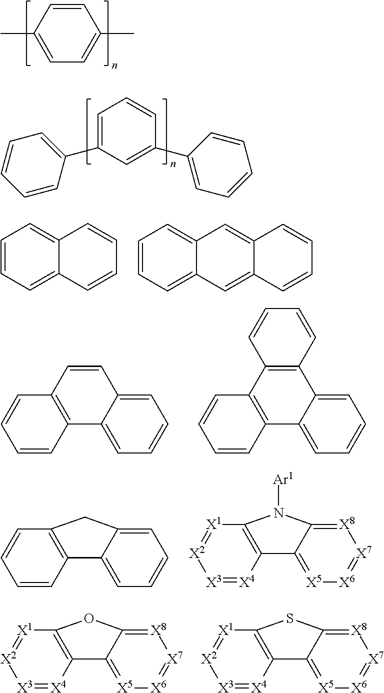

wherein n is an integer of 1 to 20; X¹ to X⁸ are each CH or N; and Ar¹ is defined as above.

Further examples of cyclic aromatic amine derivative compounds can be found in U.S. Pat. No. 3,567,450, U.S. Pat. No. 4,720,432, U.S. Pat. No. 5,061,569, U.S. Pat. No. 3,615,404, and U.S. Pat. No. 5,061,569.

Examples of a metal complex which can be used as HTM or HIM include (but are not limited to) a general structure below:

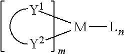

wherein M is a metal with an atomic weight greater than 40; (Y¹—Y²) is a bidentate ligand, in which Y¹ and Y² are independently selected from C, N, O, P and S; L is an auxiliary ligand; m is an integer from 1 to a maximum coordination number of the metal; and m+n is the maximum coordination number of the metal.

In one embodiment, (Y¹-Y²) is a 2-phenylpyridine derivative.

In another embodiment, (Y¹-Y²) is a carbene ligand.

In another embodiment, M is selected from Ir, Pt, Os and Zn.

In another aspect, HOMO of the metal complex is greater than −5.5 eV (relative to a vacuum level).

Suitable examples of HIM/HTM compounds are listed below:

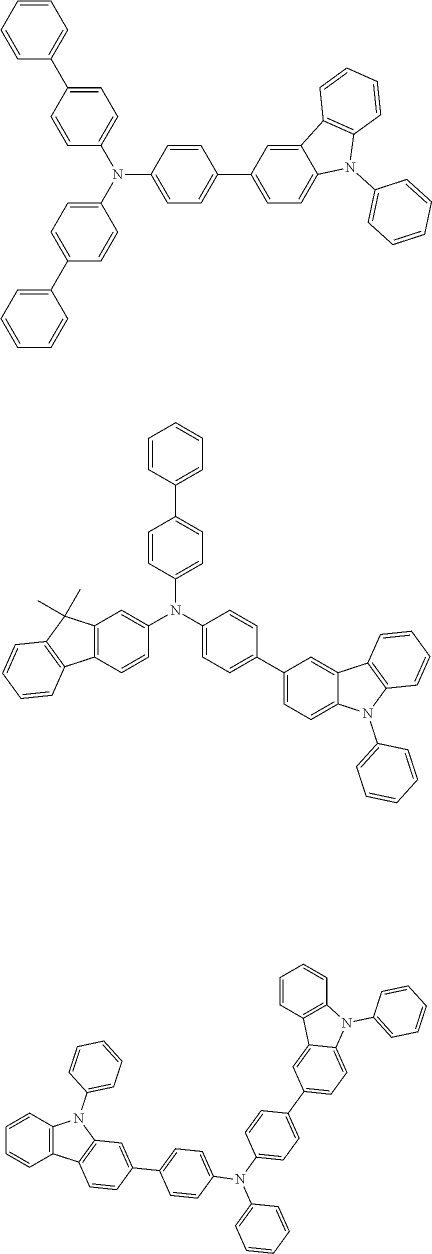 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc(-c3ccc4c(c3)c3ccccc3n4-c3ccccc3)cc2)c2ccc(-c3ccc4c5ccccc5n(-c5ccccc5)c4c3)cc2)cc1]

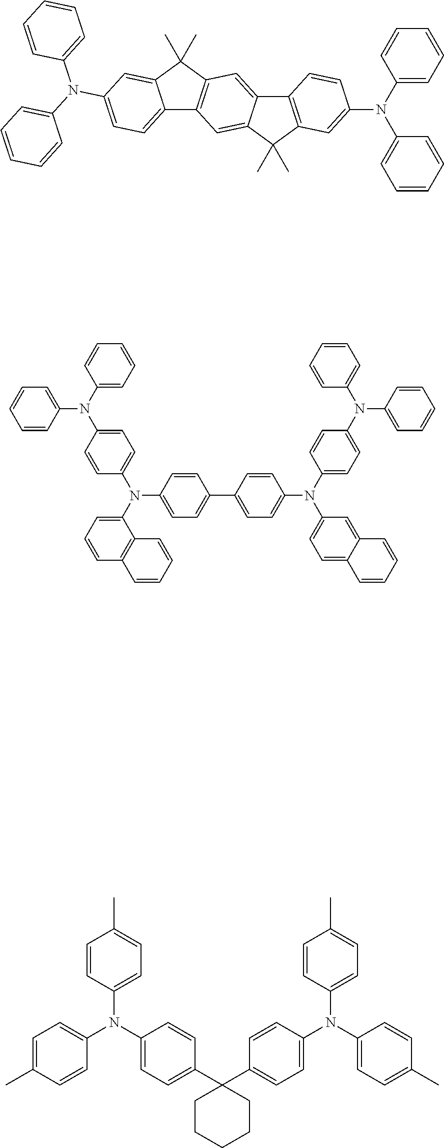

2. Triplet Host Material (Triplet Host)

Examples of triplet host materials are not particularly limited, and any metal complex or organic compound can be used as a host material, as long as its triplet state energy is higher than that of a light emitter, particularly a triplet emitter or a phosphorescent emitter. Examples of metal complexes which can be used as the triplet host include (but are not limited to) a general structure below:

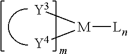

wherein M is a metal; (Y³-Y⁴) is a bidentate ligand, in which Y³ and Y⁴ are independently selected from C, N, O, P and S; L is an auxiliary ligand; m is an integer of from 1 to a maximum coordination number of the metal; and m+n is the maximum coordination number of the metal.

In one embodiment, the metal complex which can used as the triplet host has one of following forms:

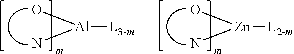

wherein (O—N) is a bidentate ligand, and the metal is coordinated with the O and N atoms.

In one embodiment, M may be selected from Ir and Pt.

Examples of organic compounds which can be used as the triplet host are selected from compounds having a cyclic aromatic hydrocarbon group (such as, benzene, biphenyl, triphenyl, benzo, and fluorene), compounds a having heteroaromatic group (such as, dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, oxazole, dibenzoxazole, benzisoxazole, benzothiazole, quinoline, isoquinoline, cinnoline, phthalazine, quinazoline, quinoxaline, naphthalene, phthalein, pteridine, xanthene, acridine, phenazine, phenthiazine, phenoxazine, benzofuropyridine, furopyridine, benzothienopyridine, thienopyridine, benzoselenophenopyridine and selenophene-benzodipyridine); or compounds containing groups having 2-10 rings, these groups may be, identically or differently, cyclic aromatic hydrocarbon groups or heterocyclic aromatic groups and bonded to each other directly or through at least one of following groups: an oxygen atom, a nitrogen atom, a sulfur atom, a silicon atom, a phosphorous atom, a boron atom, a chain structural unit and an aliphatic ring. Each Ar may be further substituted by a substituent, which may be selected from hydrogen, alkyl, alkoxy, amino, alkenyl, alkynyl, aralkyl, heteroalkyl, aryl, and heteroaryl.

In one embodiment, the triplet host material can be selected from compounds containing at least one of following groups:

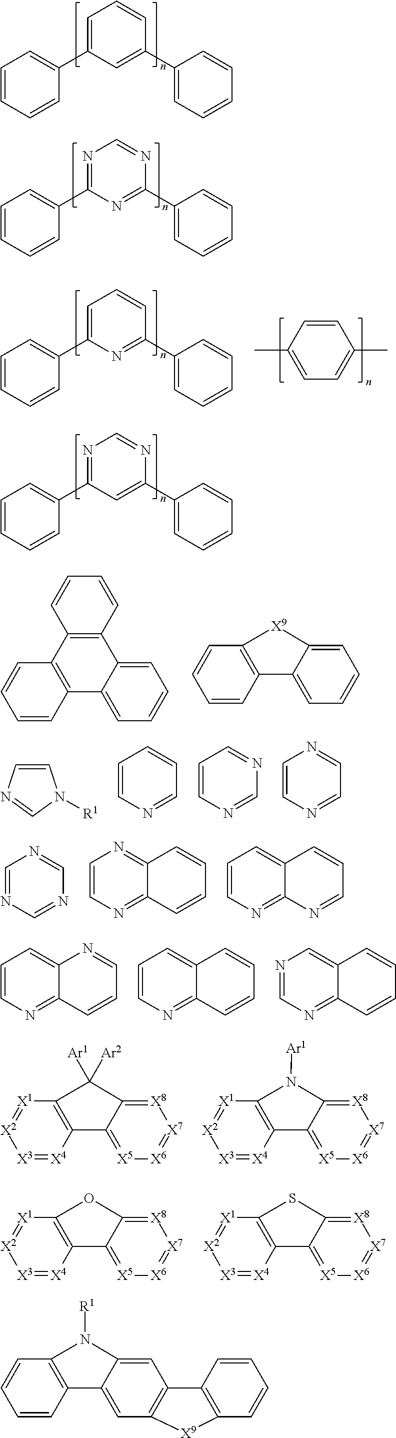

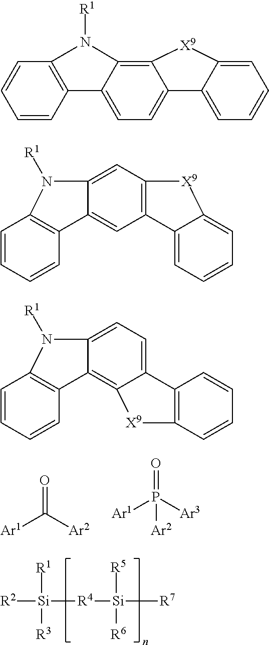

wherein R¹-R⁷ are each independently selected from hydrogen, alkyl, alkoxy, amino, alkenyl, alkynyl, aralkyl, heteroalkyl, aryl, and heteroaryl; when R¹-R⁷ are aryl or heteroaryl, they have the same meaning as Ar¹ and Ar²; n is an integer of 0 to 20; X¹-X⁸ are each selected from CH or N; and X⁹ is selected from CR¹R² or NR¹.

Suitable examples of the triplet host materials are listed below:

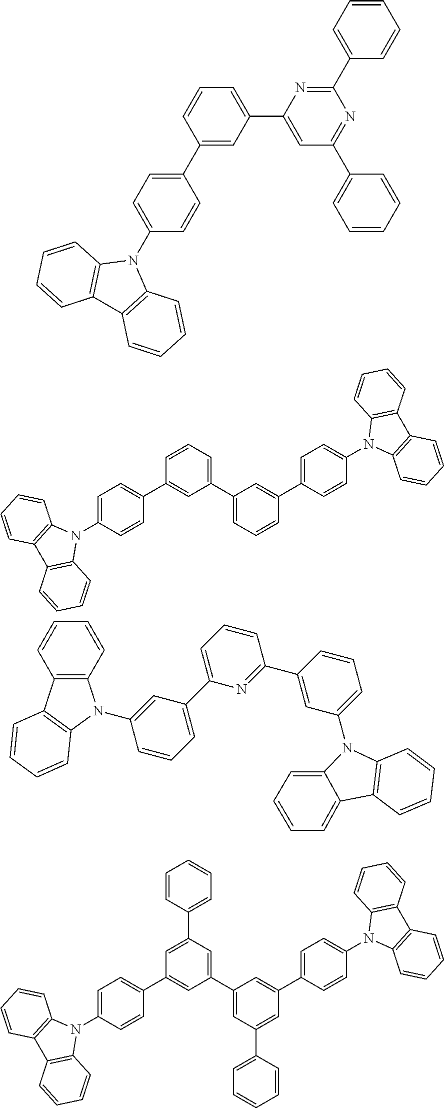

3. Singlet Host Material (Singlet Host)

Examples of singlet host materials are not particularly limited, any organic compound may be used as a host material, as long as its singlet state energy is higher than that of a light emitter, particularly a singlet emitter or a fluorescence emitter.

Examples of organic compounds used as singlet host materials can be selected from cyclic aromatic hydrocarbon compounds (such as, benzene, biphenyl, triphenyl, benzo, naphthalene, anthracene, phenalene, phenanthrene, fluorene, pyrene, chrysene, perylene, azulene), heterocyclic aromatic compounds (such as, dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indolizine, benzoxazole, benzisoxazole, benzothiazole, quinoline, isoquinoline, cinnoline, quinazoline, quinoxaline, naphthalene, phthalein, pteridine, xanthene, acridine, phenazine, phenthiazine, phenoxazine, benzofuropyridine, furodipyridine, benzothienopyridine, thienodipyridine, benzoselenophenopyridine and selenodipyridine); compounds containing groups having 2-10 rings, these groups may be, identically or differently, cyclic aromatic hydrocarbon groups or heterocyclic aromatic groups and bonded to each other directly or through at least one of following groups: an oxygen atom, a nitrogen atom, a sulfur atom, a silicon atom, a phosphorous atom, a boron atom, a chain structural unit and an cyclic aliphatic group.

In one embodiment, the singlet host material may be selected from compounds containing at least one of following groups:

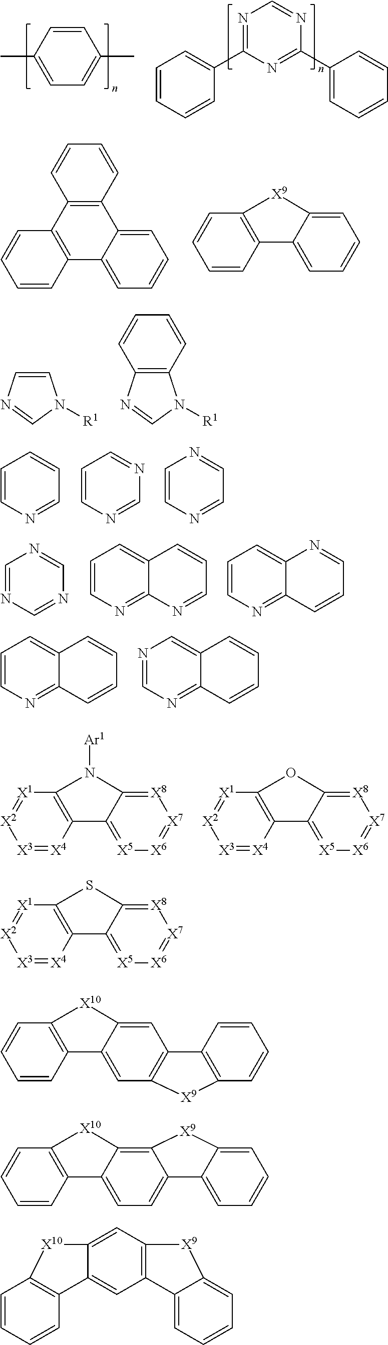

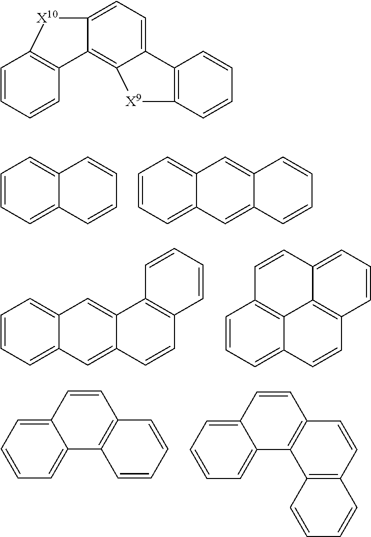

wherein R¹ can be independently selected from hydrogen, alkyl, alkoxy, amino, alkenyl, alkynyl, aralkyl, heteroalkyl, aryl, and heteroaryl; Ar¹ is aryl or heteroaryl, and has the same definition as Ar¹ in the above HTM; n is an integer of 0 to 20; X¹—X⁸ are each selected from CH or N; and X⁹ and X¹⁰ are each selected from CR¹R² or NR¹.

Some examples of anthryl-containing singlet host materials are listed below:

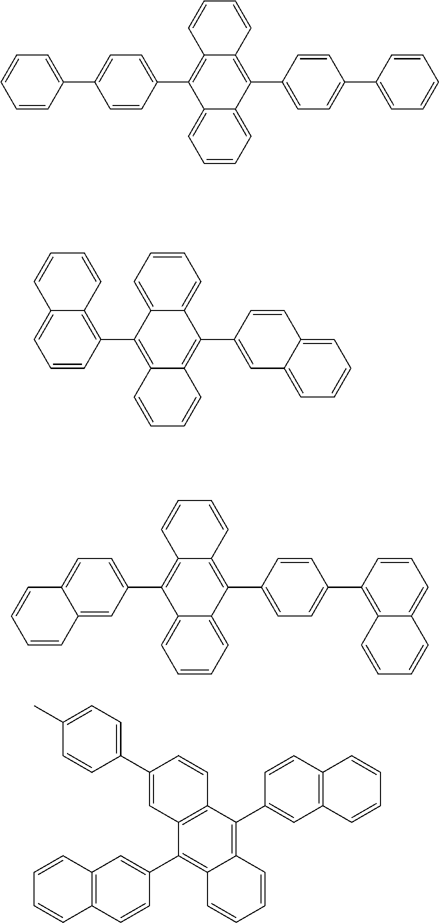

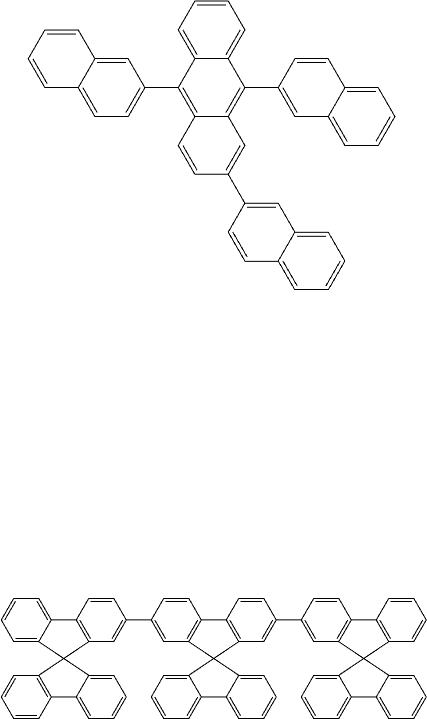

4. Singlet Emitter

A singlet emitter typically has a longer conjugated π electron system. So far, there have been many examples, such as, styrylamines and derivatives thereof disclosed in JP2913116B and WO2001021729A1, and indenofluorene and derivatives thereof disclosed in WO2008/006449 and WO2007/140847.

In one embodiment, the singlet emitter may be selected from monostyrylamines, distyrylamines, tristyrylamines, tetrastyrylamines, styryl phosphines, styrylethers and arylamines.

A monostyrylamine refers to a compound containing one unsubstituted or substituted styryl group and at least one amine, which can be aromatic. A distyrylamine refers to a compound containing two unsubstituted or substituted styryl groups and at least one amine, which can be aromatic. A tristyrylamine refers to a compound containing three unsubstituted or substituted styryl groups and at least one amine, which can be aromatic. A tetrastyrylamine refers to a compound containing four unsubstituted or substituted styryl groups and at least one amine, which can be aromatic. One example of styryl is distyryl, which may be further substituted. Phosphines and ethers are defined analogously thereto. An arylamine or an aromatic amine refers to a compound containing three unsubstituted or substituted aromatic or heteroaromatic ring systems bonded directly to the nitrogen, at least one of which can be a condensed ring system having at least 14 aromatic ring atoms. Some examples thereof include aromatic anthracenamines, aromatic anthracenediamines, aromatic pyrenamines, aromatic pyrenediamines, aromatic chrysenamines, and aromatic chrysenediamines. An aromatic anthracenamine refers to a compound in which a diarylamino group is bonded directly to an anthracene group, such as in the 9-position. An aromatic anthracenediamine refers to a compound in which two diarylamino groups are bonded directly to an anthracene group, for example, at the 9,10-position. Aromatic pyrenamines, aromatic pyrenediamines, aromatic chrysenamines and aromatic chrysenediamines are defined analogously thereto, where the diarylamino groups can be bonded to the pyrene at the 1-position or at the 1,6-position.

Examples of singlet emitters based on vinyl amines and aryl amines can be found in the following patent documents: WO 2006/000388, WO 2006/058737, WO 2006/000389, WO 2007/065549, WO 2007/115610, U.S. Pat. No. 7,250,532 B2, DE 102005058557 A1, CN 1583691 A, JP 08053397 A, U.S. Pat. No. 6,251,531 B1, US 2006/210830 A, EP 1957606 A1 and US 2008/0113101 A1, the entire contents of which are incorporated herein by reference.

Examples of singlet emitters based on distyrylbenzene and derivatives thereof can be found in U.S. Pat. No. 5,121,029.

Further singlet emitters can be selected from indenofluorenamines or indenofluorenediamines, for example in accordance with WO 2006/122630, benzoindenofluorenamines or benzoindenofluorenediamines, for example in accordance with WO 2008/006449, and dibenzoindenofluorenamines or dibenzoindenofluorenediamines, for example in accordance with WO 2007/140847.

Other materials which may be used as the singlet emitter include polycyclic aromatic compounds, particularly derivatives of the following compounds: anthracene (such as, 9, 10-di(2-naphthanthracene), naphthalene, tetracene, xanthene, phenanthrene, pyrene (such as, 2,5,8,11-tetra-t-butylpyrene), indenopyrene, phenylene (such as, 4,4′-di(9-ethyl-3-vinylcarbazole)-1,1′-biphenyl), diindenopyrene, decacyclene, coronene, fluorene, spirobifluorene, arylpyrene (such as, disclosed in US20060222886), arylene ethylene (such as, disclosed in U.S. Pat. No. 5,121,029 and U.S. Pat. No. 5,130,603), cyclopentadiene (such as, tetraphenylcyclopentadiene), rubrene, coumarin, rhodamine, quinacridone, pyran (such as, 4-(dicyanomethylene)-6-(4-p-dimethylaminostyryl-2-methyl)-4H-pyran, DCM), thiopyran, bis(azinyl)imine boron (disclosed in US 2007/0092753 A1), bis(azinyl)methene compounds, carbostyryl compounds, pentoxazone, benzoxazole, benzothiazole, benzimidazole and diketopyrrolopyrrole. Some singlet emitter materials can be found in the following patent documents: US 20070252517 A1, U.S. Pat. No. 4,769,292, U.S. Pat. No. 6,020,078, US 2007/0252517 A1 and US 2007/0252517 A1, the entire contents of which are incorporated herein by reference.

Some suitable examples of singlet emitters are listed below:

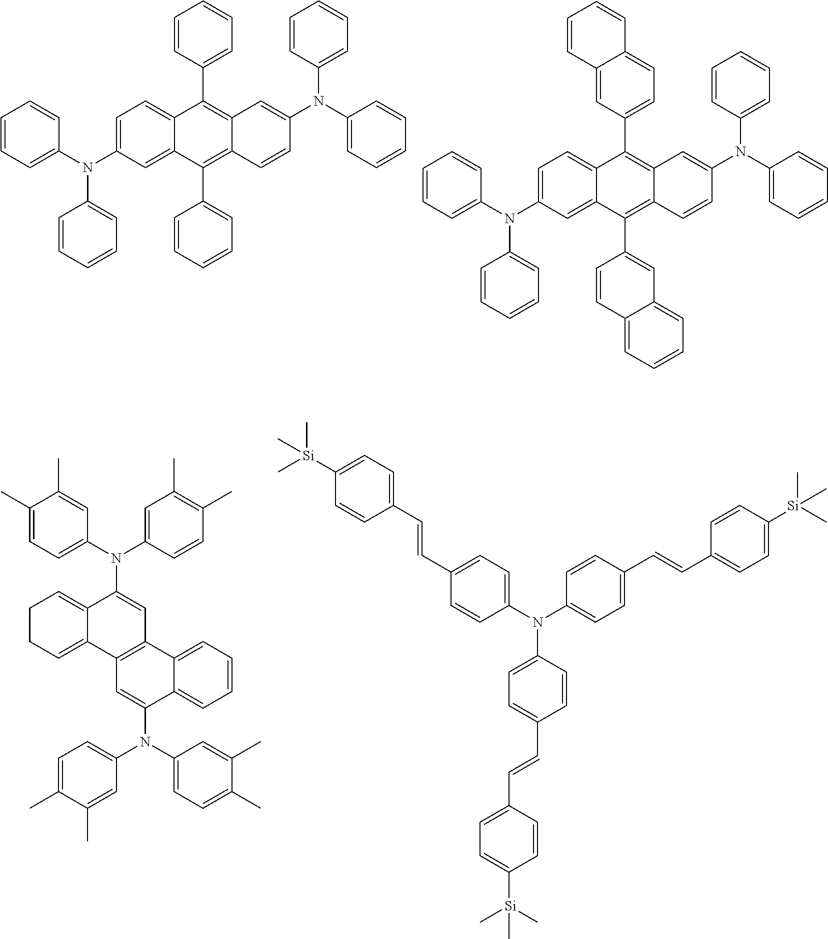

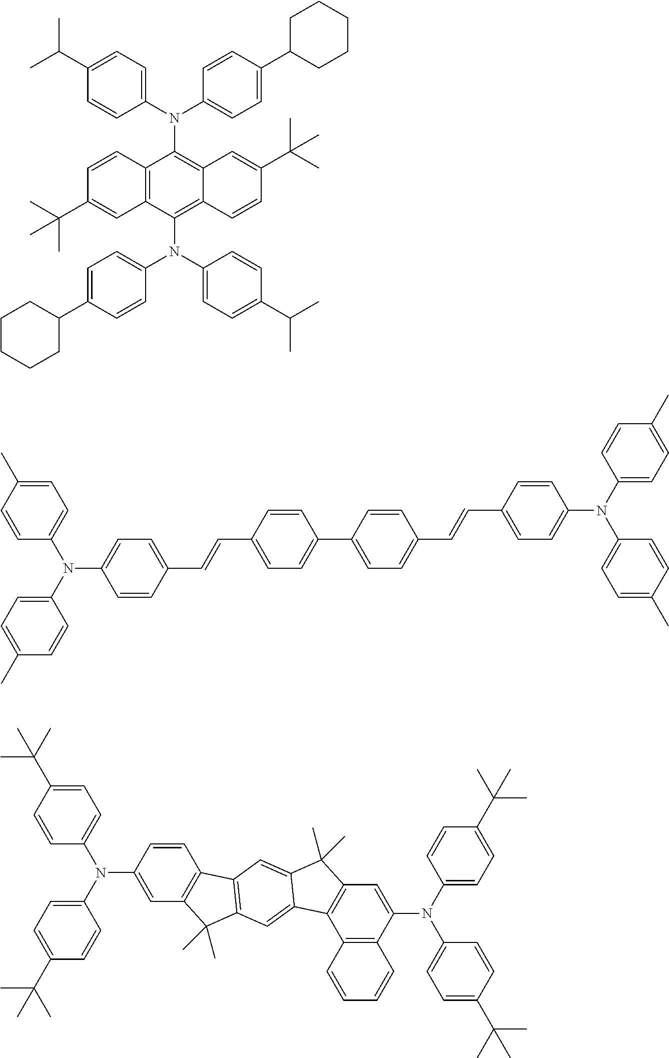

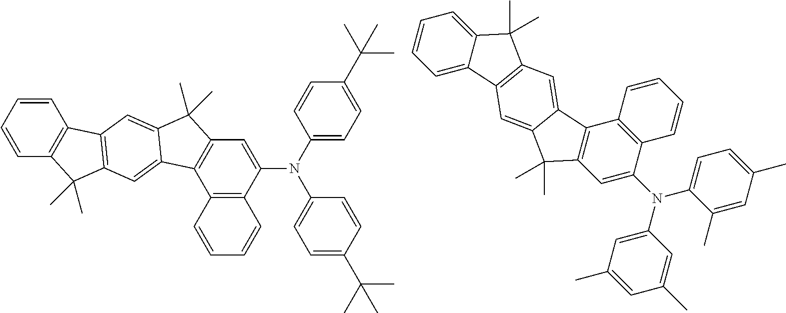

5. Thermally Activated Delayed Fluorescence (TADF)

Traditional organic fluorescent materials only can use 25% of singlet excitons formed by electrical excitation to emit light, thus the internal quantum efficiency of devices is low (at most 25%). Although intersystem crossing of phosphorescent materials is improved due to strong spin-orbit coupling at heavy atom centers, they can effectively use singlet excitons and triplet excitons formed by electrical excitation to emit light, so as to achieve 100% internal quantum efficiency of the devices. However, problems of phosphorescent materials, such as, high cost, poor stability and serious rolling-off of devices, limit their application in OLED. Thermally activated delayed fluorescence materials are the third generation of organic light-emitting materials developed after organic fluorescent materials and organic phosphorescent materials. Such materials typically have a small singlet-triplet energy level difference (ΔEst), so that triplet excitons can be converted into singlet excitons through intersystem crossing for emitting light. In this way, singlet excitons and triplet excitons formed by electrical excitation can be utilized fully and internal quantum efficiency of devices can reach 100%.

TADF materials require a smaller singlet-triplet energy level difference. ΔEst is typically less than 0.3 eV, in one embodiment is less than 0.2 eV, in another embodiment is 0.1 eV, and in yet another embodiment is 0.05 eV. In one embodiment, TADF has a better fluorescent quantum efficiency. Some TADF light-emitting materials may be found in following patent documents: CN103483332 (A), TW201309696 (A), TW201309778 (A), TW201343874 (A), TW201350558 (A), US20120217869 (A1), WO2013133359 (A1), WO2013154064 (A1), Adachi, et. al. Adv. Mater., 21, 2009, 4802, Adachi, et. al. Appl. Phys. Lett., 98, 2011, 083302, Adachi, et. al. Appl. Phys. Lett., 101, 2012, 093306, Adachi, et. al. Chem. Commun., 48, 2012, 11392, Adachi, et. al. Nature Photonics, 6, 2012, 253, Adachi, et. al. Nature, 492, 2012, 234, Adachi, et. al. J. Am. Chem. Soc, 134, 2012, 14706, Adachi, et. al. Angew. Chem. Int. Ed, 51, 2012, 11311, Adachi, et. al. Chem. Commun., 48, 2012, 9580, Adachi, et. al. Chem. Commun., 48, 2013, 10385, Adachi, et. al. Adv. Mater., 25, 2013, 3319, Adachi, et. al. Adv. Mater., 25, 2013, 3707, Adachi, et. al. Chem. Mater., 25, 2013, 3038, Adachi, et. al. Chem. Mater., 25, 2013, 3766, Adachi, et. al. J. Mater. Chem. C., 1, 2013, 4599, and Adachi, et. al. J. Phys. Chem. A., 117, 2013, 5607, the entire contents of which are incorporated herein by reference.

Some suitable examples of TADF materials are listed in a table below:

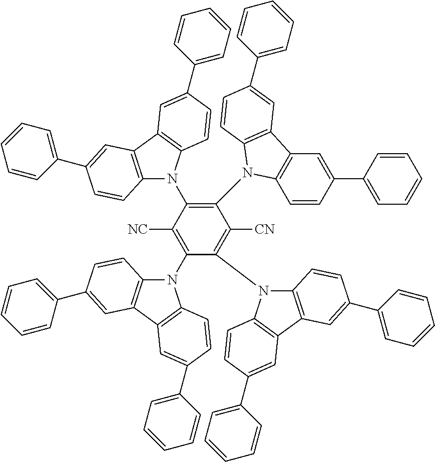 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21]

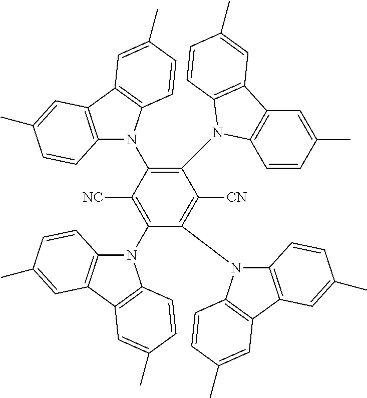

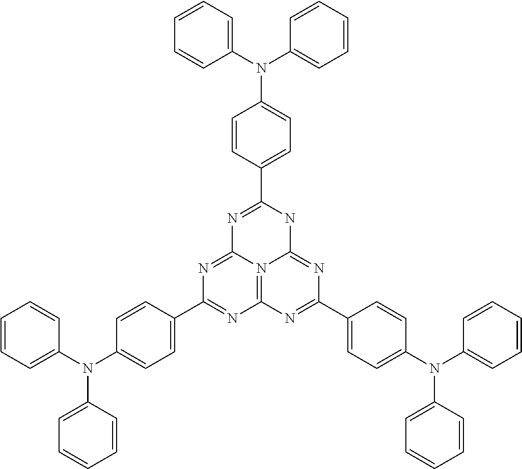

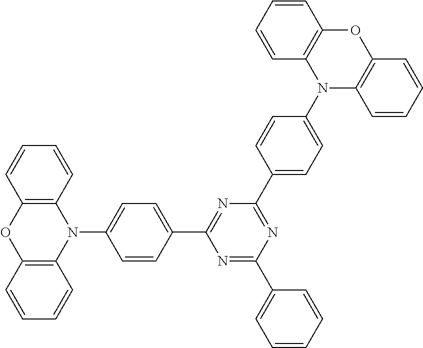 [SMILES: c1ccc(-c2nc(-c3ccc(N4c5ccccc5Oc5ccccc54)cc3)nc(-c3ccc(N4c5ccccc5Oc5ccccc54)cc3)n2)cc1]

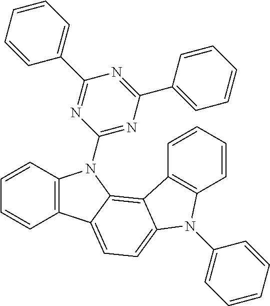 [SMILES: c1ccc(-c2nc(-c3ccccc3)nc(-n3c4ccccc4c4ccc5c(c6ccccc6n5-c5ccccc5)c43)n2)cc1]

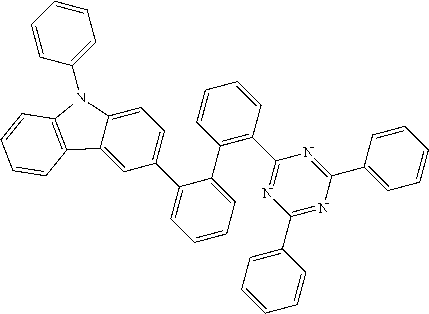 [SMILES: c1ccc(-c2nc(-c3ccccc3)nc(-c3ccccc3-c3ccccc3-c3ccc4c(c3)c3ccccc3n4-c3ccccc3)n2)cc1]

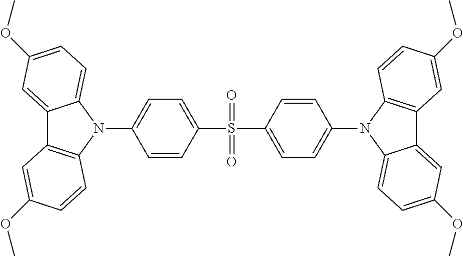 [SMILES: COc1ccc2c(c1)c1cc(OC)ccc1n2-c1ccc(S(=O)(=O)c2ccc(-n3c4ccc(OC)cc4c4cc(OC)ccc43)cc2)cc1]

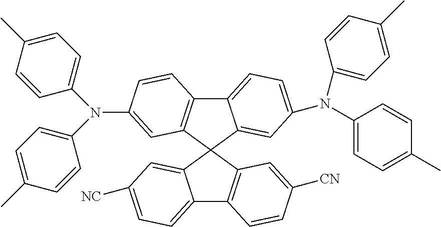

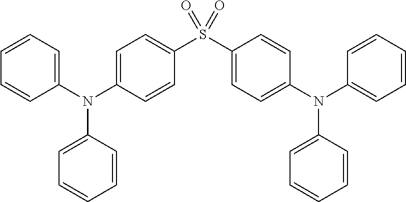 [SMILES: O=S(=O)(c1ccc(N(c2ccccc2)c2ccccc2)cc1)c1ccc(N(c2ccccc2)c2ccccc2)cc1]

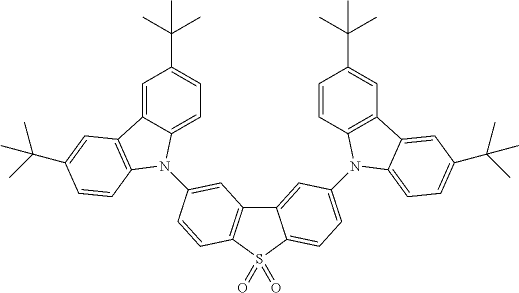 [SMILES: CC(C)(C)c1ccc2c(c1)c1cc(C(C)(C)C)ccc1n2-c1ccc2c(c1)-c1cc(-n3c4ccc(C(C)(C)C)cc4c4cc(C(C)(C)C)ccc43)ccc1S2(=O)=O]

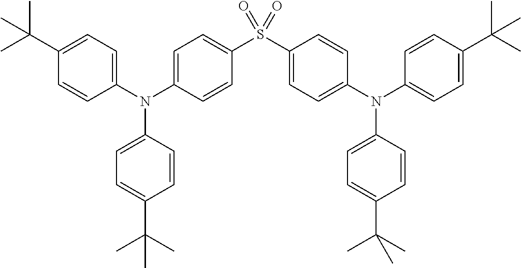 [SMILES: CC(C)(C)c1ccc(N(c2ccc(C(C)(C)C)cc2)c2ccc(S(=O)(=O)c3ccc(N(c4ccc(C(C)(C)C)cc4)c4ccc(C(C)(C)C)cc4)cc3)cc2)cc1]

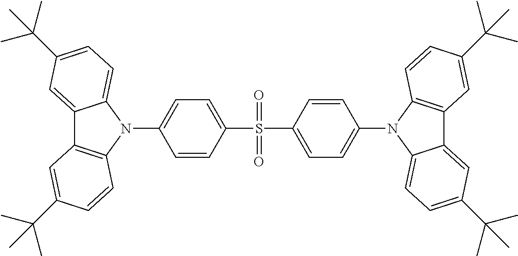 [SMILES: CC(C)(C)c1ccc2c(c1)c1cc(C(C)(C)C)ccc1n2-c1ccc(S(=O)(=O)c2ccc(-n3c4ccc(C(C)(C)C)cc4c4cc(C(C)(C)C)ccc43)cc2)cc1]

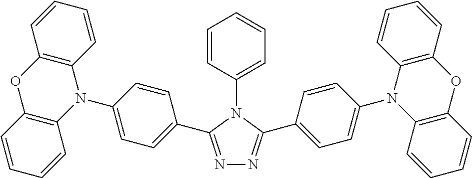 [SMILES: c1ccc(-n2c(-c3ccc(N4c5ccccc5Oc5ccccc54)cc3)nnc2-c2ccc(N3c4ccccc4Oc4ccccc43)cc2)cc1]

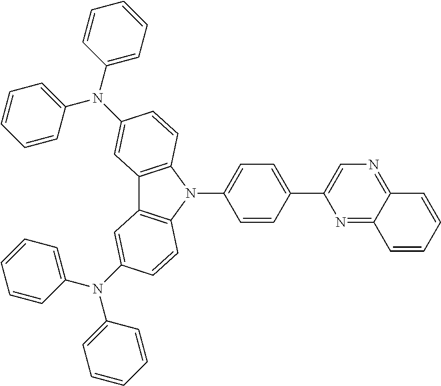 [SMILES: c1ccc(N(c2ccccc2)c2ccc3c(c2)c2cc(N(c4ccccc4)c4ccccc4)ccc2n3-c2ccc(-c3cnc4ccccc4n3)cc2)cc1]

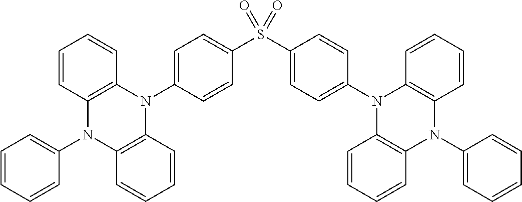 [SMILES: O=S(=O)(c1ccc(N2c3ccccc3N(c3ccccc3)c3ccccc32)cc1)c1ccc(N2c3ccccc3N(c3ccccc3)c3ccccc32)cc1]

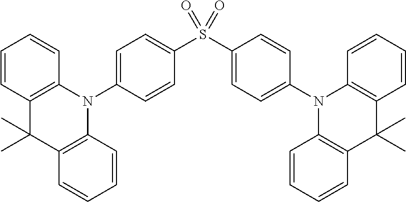 [SMILES: CC1(C)c2ccccc2N(c2ccc(S(=O)(=O)c3ccc(N4c5ccccc5C(C)(C)c5ccccc54)cc3)cc2)c2ccccc21]

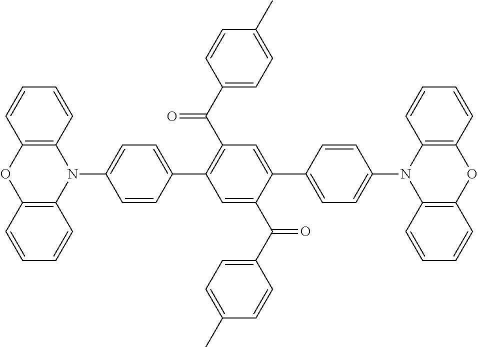 [SMILES: Cc1ccc(C(=O)c2cc(-c3ccc(N4c5ccccc5Oc5ccccc54)cc3)c(C(=O)c3ccc(C)cc3)cc2-c2ccc(N3c4ccccc4Oc4ccccc43)cc2)cc1]

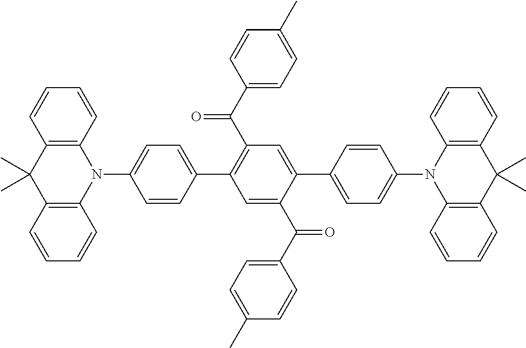

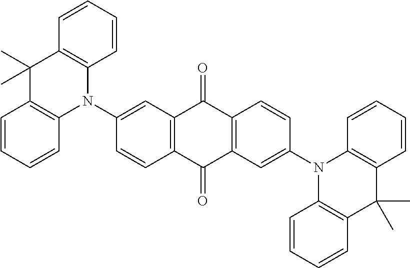 [SMILES: CC1(C)c2ccccc2N(c2ccc3c(c2)C(=O)c2ccc(N4c5ccccc5C(C)(C)c5ccccc54)cc2C3=O)c2ccccc21]

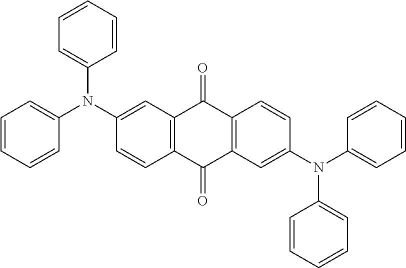 [SMILES: O=C1c2ccc(N(c3ccccc3)c3ccccc3)cc2C(=O)c2ccc(N(c3ccccc3)c3ccccc3)cc21]

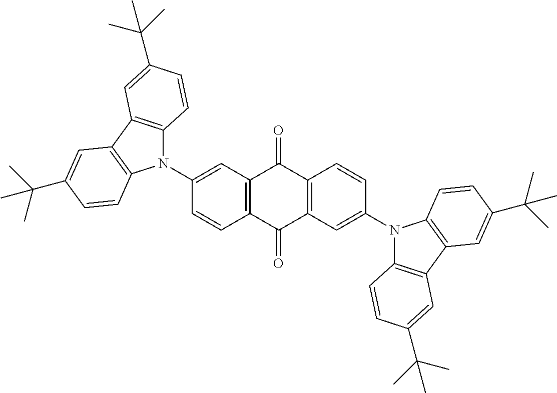 [SMILES: CC(C)(C)c1ccc2c(c1)c1cc(C(C)(C)C)ccc1n2-c1ccc2c(c1)C(=O)c1ccc(-n3c4ccc(C(C)(C)C)cc4c4cc(C(C)(C)C)ccc43)cc1C2=O]

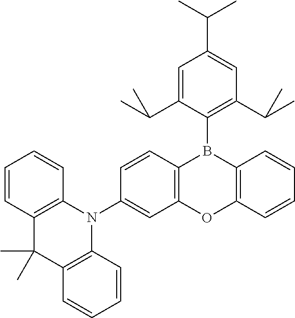 [SMILES: CC(C)c1cc(C(C)C)c(B2c3ccccc3Oc3cc(N4c5ccccc5C(C)(C)c5ccccc54)ccc32)c(C(C)C)c1]

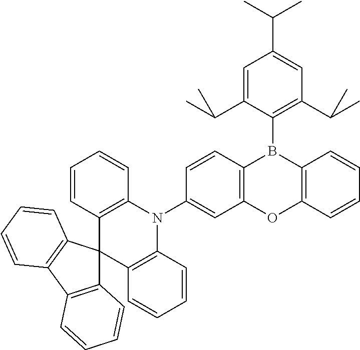 [SMILES: CC(C)c1cc(C(C)C)c(B2c3ccccc3Oc3cc(N4c5ccccc5C5(c6ccccc6-c6ccccc65)c5ccccc54)ccc32)c(C(C)C)c1]

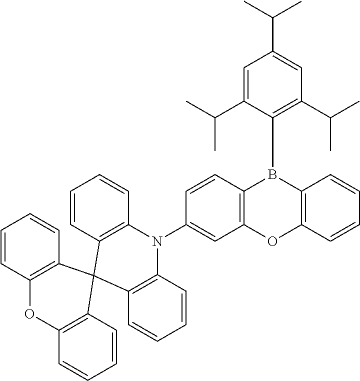 [SMILES: CC(C)c1cc(C(C)C)c(B2c3ccccc3Oc3cc(N4c5ccccc5C5(c6ccccc6Oc6ccccc65)c5ccccc54)ccc32)c(C(C)C)c1]

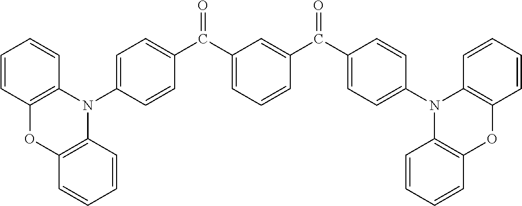 [SMILES: O=C(c1ccc(N2c3ccccc3Oc3ccccc32)cc1)c1cccc(C(=O)c2ccc(N3c4ccccc4Oc4ccccc43)cc2)c1]

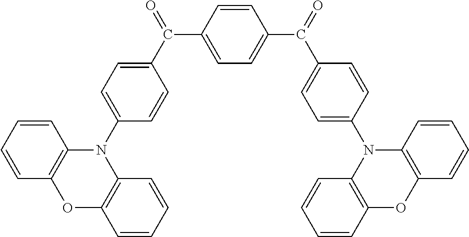 [SMILES: O=C(c1ccc(C(=O)c2ccc(N3c4ccccc4Oc4ccccc43)cc2)cc1)c1ccc(N2c3ccccc3Oc3ccccc32)cc1]

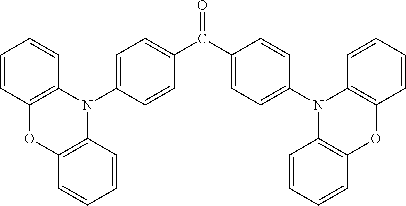 [SMILES: O=C(c1ccc(N2c3ccccc3Oc3ccccc32)cc1)c1ccc(N2c3ccccc3Oc3ccccc32)cc1]

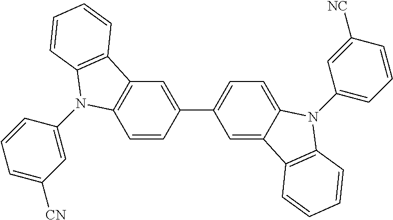 [SMILES: N#Cc1cccc(-n2c3ccccc3c3cc(-c4ccc5c(c4)c4ccccc4n5-c4cccc(C#N)c4)ccc32)c1]

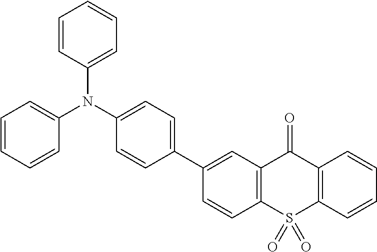 [SMILES: O=C1c2ccccc2S(=O)(=O)c2ccc(-c3ccc(N(c4ccccc4)c4ccccc4)cc3)cc21]

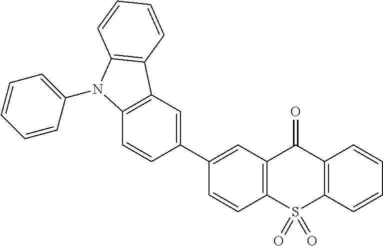 [SMILES: O=C1c2ccccc2S(=O)(=O)c2ccc(-c3ccc4c(c3)c3ccccc3n4-c3ccccc3)cc21]

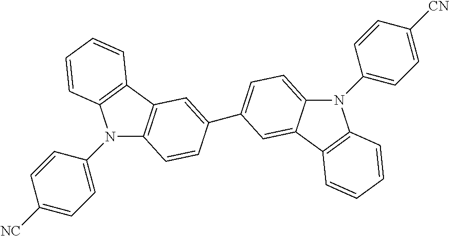 [SMILES: N#Cc1ccc(-n2c3ccccc3c3cc(-c4ccc5c(c4)c4ccccc4n5-c4ccc(C#N)cc4)ccc32)cc1]

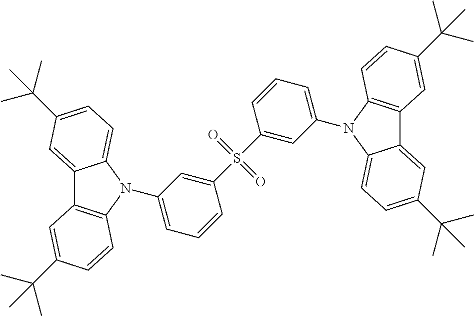 [SMILES: CC(C)(C)c1ccc2c(c1)c1cc(C(C)(C)C)ccc1n2-c1cccc(S(=O)(=O)c2cccc(-n3c4ccc(C(C)(C)C)cc4c4cc(C(C)(C)C)ccc43)c2)c1]

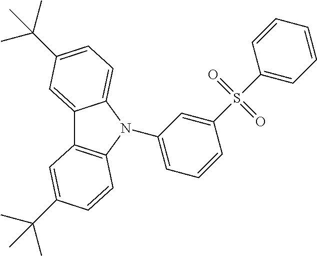 [SMILES: CC(C)(C)c1ccc2c(c1)c1cc(C(C)(C)C)ccc1n2-c1cccc(S(=O)(=O)c2ccccc2)c1]

6. Triplet Emitter

The triplet emitter is also termed as a phosphorescent emitter. In one embodiment, the triplet emitter is a metal complex having a formula of M(L)ₙ, where M is a metal atom, L on each occurrence may be same or different and is an organic ligand bonded or coordinated to the metal atom M at one or more positions, and n is an integer of greater than 1, such as 1, 2, 3, 4, 5 or 6. Optionally, these metal complexes are linked to a polymer, such as, through the organic ligand.

In one embodiment, the metal atom M is selected from transition metal elements or lanthanide elements or actinium elements. M can be selected from Ir, Pt, Pd, Au, Rh, Ru, Os, Sm, Eu, Gd, Tb, Dy, Re, Cu or Ag, and in one embodiment is Os, Ir, Ru, Rh, Re, Pd or Pt.

In one embodiment, the triplet emitter contains a chelate ligand that is a ligand coordinated to the metal through at least two bonding sites. In one embodiment, the triplet emitter contains two or three same or different bidentate or polydentate ligands. The chelate ligand facilitates improving the stability of the metal complex.

Examples of the organic ligands may be selected from phenylpyridine derivatives, 7,8-benzoquinoline derivatives, 2-(2-thienyl)pyridine derivatives, 2-(1-naphthyl)pyridine derivatives, or 2-phenylquinoline derivatives. All of these organic ligands may be substituted, for example, by fluoro or trifluoromethyl. The auxiliary ligand may be selected from acetylacetone or picric acid.

In one embodiment, the metal complexes which can be used as the triplet emitter have a form below:

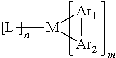

where M is metal and is selected from transition metal elements, lanthanide elements, or actinium elements. Ar¹ on each occurrence may be same or different and is a cyclic group which at least includes one donor atom, that is an atom having a lone pair of electrons, such as, nitrogen or phosphor, and the cyclic group is coordinately bonded to the metal through the donor atom. Ar² on each occurrence may be same or different and is a cyclic group which at least includes one C atom, and the cyclic group is boned to the metal through the at least one C atom. Ar¹ and Ar² are linked together by a covalent bond and each can carry one or more substituents, they may also linked together through the substituents. L on each occurrence may be same or different and is an auxiliary ligand, and the auxiliary ligand can be a bidentate chelate ligand, and in one embodiment is a single canino bidentate chelate ligand. m is 1, 2 or 3, in one embodiment is 2 or 3, and in another embodiment is 3; n is 0, 1 or 2, in one embodiment is 0 or 1, and in another embodiment is 0.

Some triplet emitter materials and the use thereof can be found in the following patent documents and literature: WO 200070655, WO 200141512, WO 200202714, WO 200215645, EP 1191613, EP 1191612, EP 1191614, WO 2005033244, WO 2005019373, US 2005/0258742, WO 2009146770, WO 2010015307, WO 2010031485, WO 2010054731, WO 2010054728, WO 2010086089, WO 2010099852, WO 2010102709, US 20070087219 A1, US 20090061681 A1, US 20010053462 A1, Baldo, Thompson et al. Nature 403, (2000), 750-753, US 20090061681 A1, US 20090061681 A1, Adachi et al. Appl. Phys. Lett. 78 (2001), 1622-1624, J. Kido et al. Appl. Phys. Lett. 65 (1994), 2124, Kido et al. Chem. Lett. 657, 1990, US 2007/0252517 A1, Johnson et al., JACS 105, 1983, 1795, Wrighton, JACS 96, 1974, 998, Ma et al., Synth. Metals 94, 1998, 245, U.S. Pat. No. 6,824,895, U.S. Pat. No. 7,029,766, U.S. Pat. No. 6,835,469, U.S. Pat. No. 6,830,828, US 20010053462A1, WO 2007095118A1, US 2012004407A1, WO 2012007088A1, WO2012007087A1, WO 2012007086A1, US 2008027220A1, WO 2011157339A1, CN 102282150A and WO 2009118087A1, the entire contents of which are incorporated herein by reference.

Some suitable examples of triplet emitters are listed in the table below:

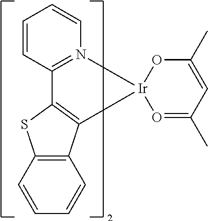

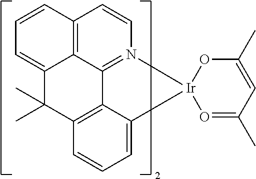

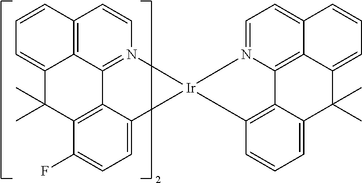

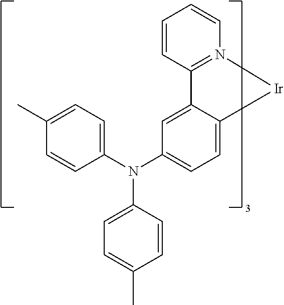

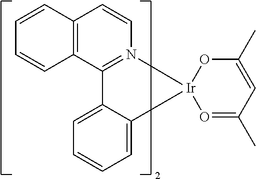

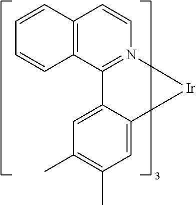

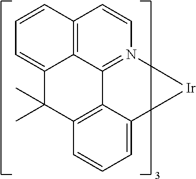

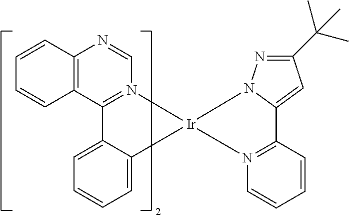

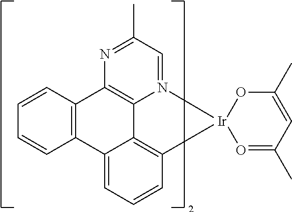

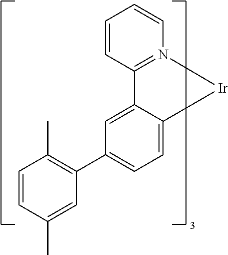

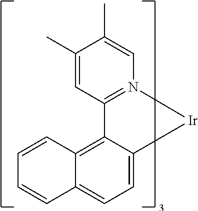

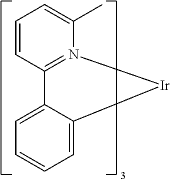

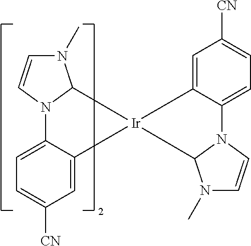

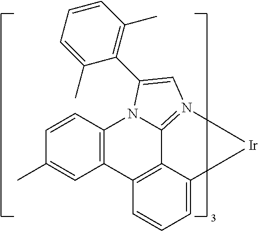

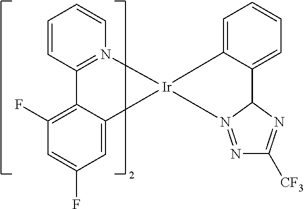

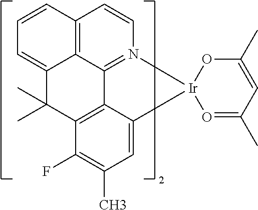

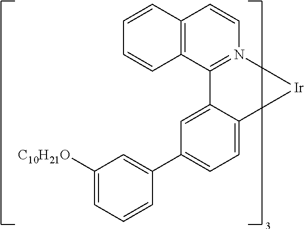

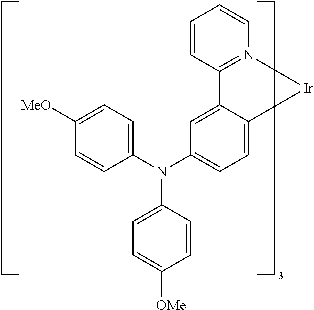

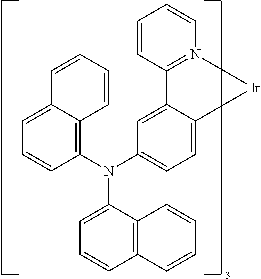

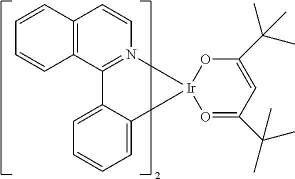

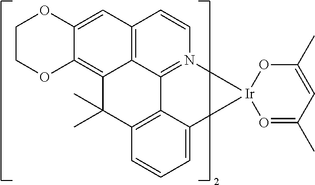

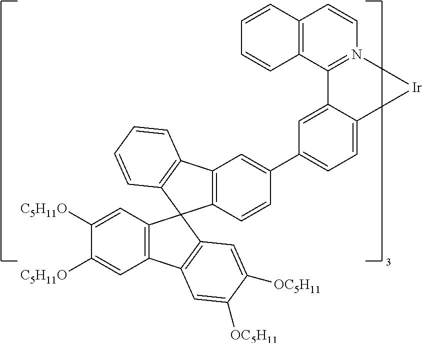

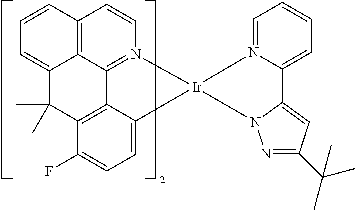

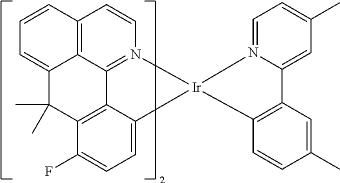

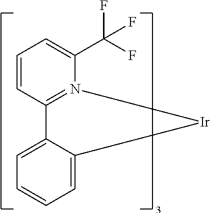

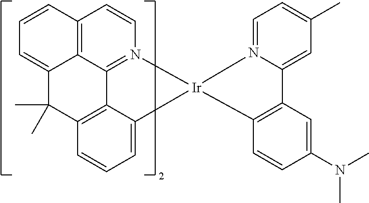

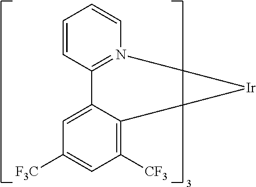

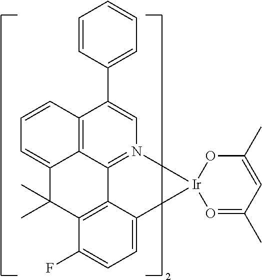

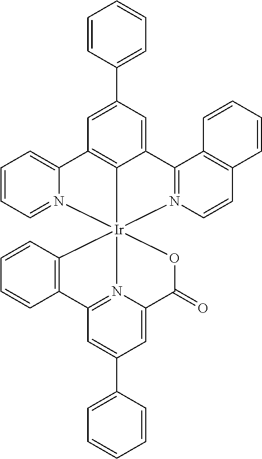

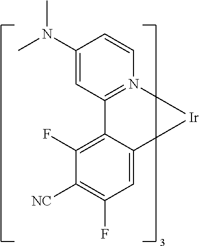

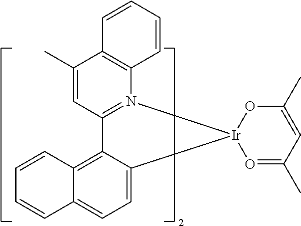

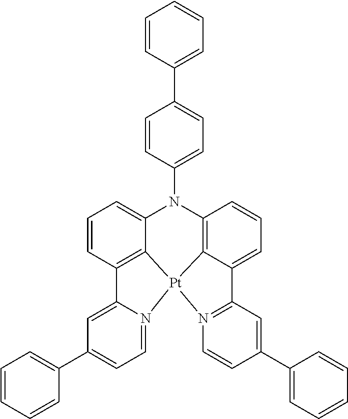

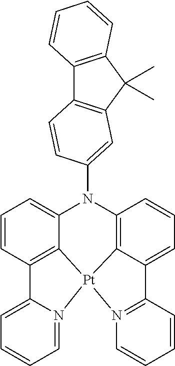

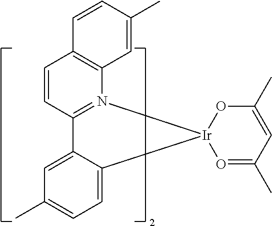

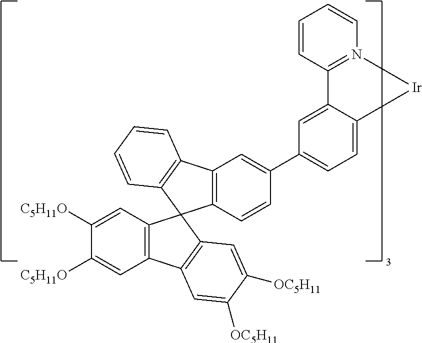

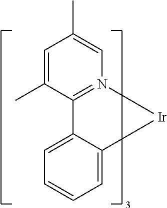

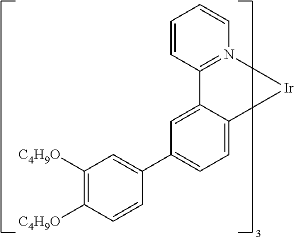

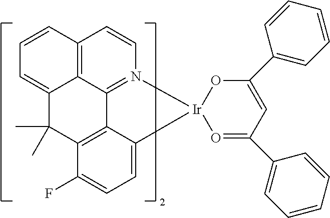

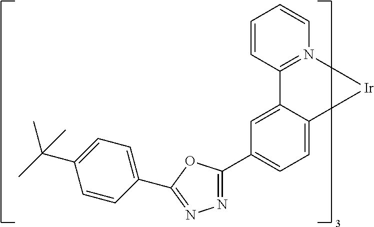

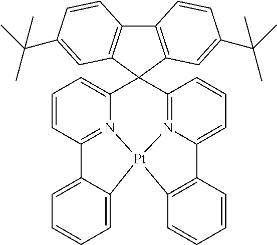

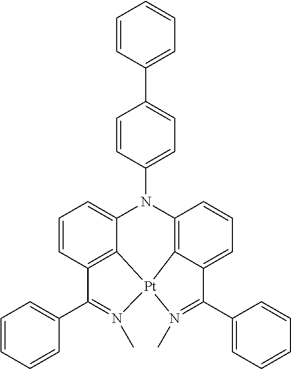

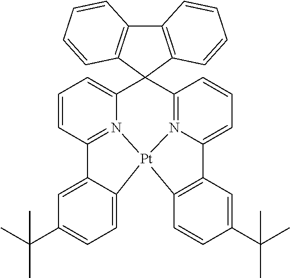

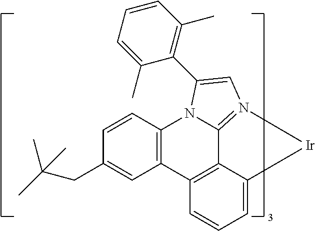

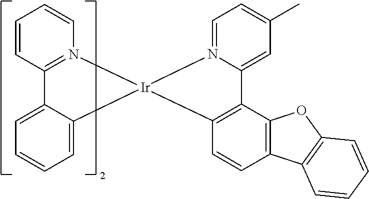

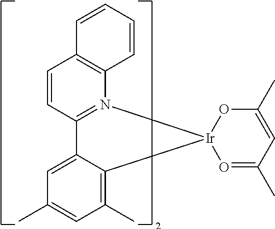

In another embodiment, the functional material in the formulation of the present disclosure is a polymer material.

Typically, the above small-molecular organic functional materials, including HIM, HTM, ETM, EIM, Host, fluorescence emitter, phosphorescent emitter and TADF, can be contained in a polymer as a repeating unit.

In one embodiment, a polymer suitable for the present disclosure is a conjugated polymer. Typically, the conjugated polymer has following formula:

BₓA_{y} Formula 1

wherein B and A on multiple occurrence are independently same or different structural units.

B: a π-conjugated structural unit having a larger energy gap and also referred to as a backbone unit, which is selected from monocyclic or polycyclic aryl or heteroaryl, such as in the form of benzene, biphenylene, naphthalene, anthracene, phenanthrene, dihydrophenanthrene, 9,10-dihydrophenanthrene, fluorene, difluorene, spirobifluorene, phenylacetylene, trans-indenofluorene, cis-indenofluorene, dibenzindenofluorene, indenonaphthalene and derivatives thereof.

A: a π-conjugated structural unit having a smaller energy gap and also referred to as a functional unit, which, depending upon different function requirements, can be selected from structural units of the above hole-injection or hole-transport material (HIM/HTM), electron-injection or electron-transport material (EIM/ETM), host material (Host), singlet emitter (fluorescence emitter) and multiplet emitter (phosphorescent emitter).

x,y:>0,x+y=1.

In some more embodiments, the functional material in the formulation of the present disclosure is the polymer HTM.

In one embodiment, the polymer HTM is a homopolymer and the homopolymer is selected from polythiophene, polypyrrole, polyaniline, poly(biphenyl triarylamine), polyvinyl carbazole, and derivatives thereof

In another embodiment, the polymer HTM is a conjugated copolymer represented by formula 1, wherein,

A: a functional group having hole-transport ability, which can be, identically or differently, selected from structural units of the above hole-injection or hole-transport material (HIM/HTM). In one embodiment, A is selected from amine, biphenyl triarylamine, thiophene, fused thiophene, pyrrole, aniline, carbazole, indenocarbazole, indolocarbazole, pentacene, phthlocyanine, porphyrinogen and derivatives thereof.

x, y: >0, x+y=1; typically y≥0.10, in one embodiment y≥0.15, in another embodiment y≥0.20, and in yet another embodiment x=y=0.5.

Listed below are suitable examples of conjugated polymers as HTM:

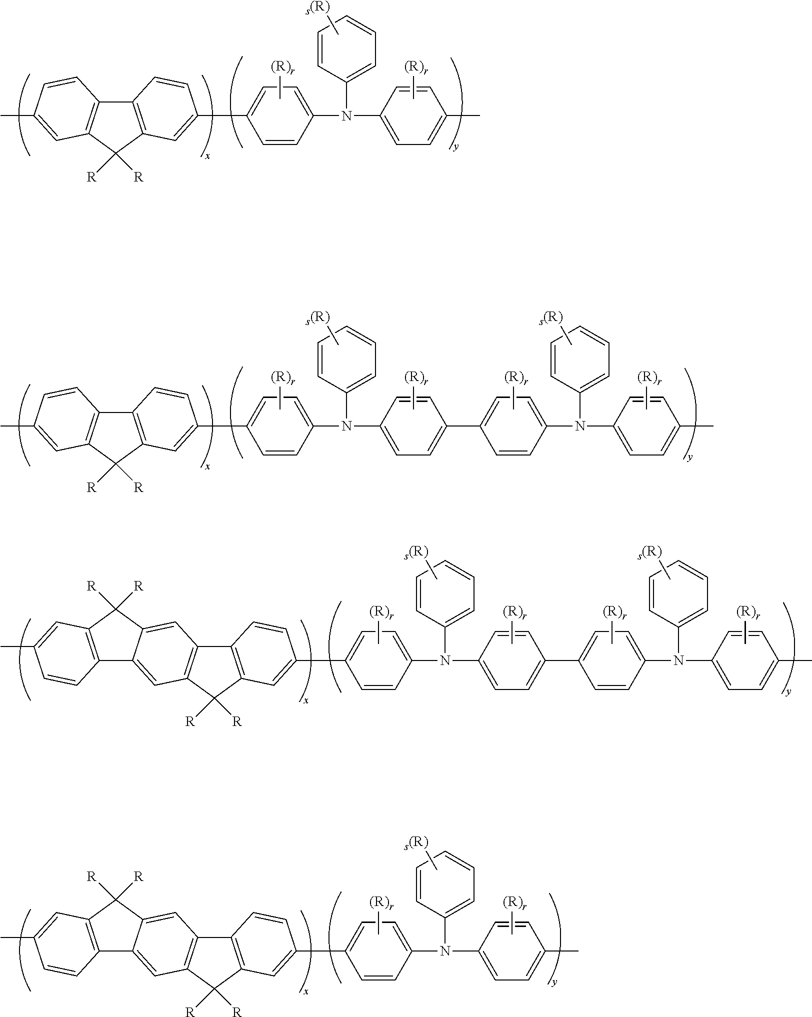

wherein, R is each independently hydrogen, straight-chain alkyl, straight-chain alkoxy or straight-chain thioalkoxy each containing 1-20 C atoms; branched or cyclic alkyl, branched or cyclic alkoxy, branched or cyclic thioalkoxy or branched or cyclic silyl each containing 3-20 C atoms, substituted C₁-C₂₀ keto, C₂-C₂₀ alkoxycarbonyl, C₇-C₂₀ aryloxycarbonyl, cyano (—CN), carbamoyl (—C(═O)NH₂), haloformyl (—C(═O)—X, where X represents a halogen atom), formyl (—C(═O)—H), isocyano, an isocyanate group, a thiocyanate group or an isothiocyanate group, hydroxyl, nitro, a CF₃ group, Cl, Br, F, a crosslinkable group or a substituted or unsubstituted 5- to 40-membered aromatic or heteroaromatic ring, or a 5- to 40-membered aryloxy or heteroaryloxy ring, or any combination thereof, where one or more R can form a monocyclic or polycyclic aliphatic or aromatic ring system with each other and/or with a ring bonded to the R group;

r is 0, 1, 2, 3 or 4;

s is 0, 1, 2, 3, 4 or 5;

x, y: >0, x+y=1; typically y≥0.10, in one embodiment y≥0.15, in another embodiment y≥0.20, and in yet another embodiment x=y=0.5.

Another organic functional material is a polymer having electron-transport ability, including a conjugated polymer and a non-conjugated polymer.

Some polymer ETM materials are homopolymers, which can be selected from polyphenanthrene, polyphenanthroline, polyindenofluorene, polyspirobifluorene, polyfluorene and derivatives thereof.

A polymer ETM material is a conjugated copolymer represented by formula 1, where A may be, on multiple occurrence, identical or different:

A is a functional group having electron-transport ability and can be selected from tri(8-hydroxyquinoline) aluminum (AlQ₃), benzene, biphenylene, naphthalene, anthracene, phenanthrene, dihydrophenanthrene, 9,10-dihydrophenanthrene, fluorene, difluorene, spirobifluorene, p-phenylene vinylene, pyrene, perylene, 9,10-dihydrophenanthrene, phenazine, phenanthroline, trans-indenofluorene, cis-indenofluorene, dibenzindenofluorene, indenonaphthalene, benzanthracene and derivatives thereof.

x, y: >0, x+y=1. typically y≥0.10, in one embodiment y≥0.15, in another embodiment y≥0.20, and in yet another embodiment x=y=0.5.

In another embodiment, the functional material in the formulation of the present disclosure is a light-emitting polymer.

In one embodiment, the light-emitting polymer is a conjugated polymer of the general formula below:

BₓA₁_{y}A₂_{z} Formula 2

wherein B: having the same definition as in the formula 1.

A₁: a functional group having hole-transport or electron-transport ability, which may be selected from structural units of the above hole-injection or hole-transport material (HIM/HTM), or electron-injection or transport material (EIM/ETM).

A₂: a group having a light-emitting function, which may be selected from structural units of the above singlet emitter (fluorescence emitter) and multiplet emitter (phosphorescent emitter).

x,y,z:>0, and x+y+z=1.

Examples of light-emitting polymers are disclosed in the following patent applications: WO2007043495, WO2006118345, WO2006114364, WO2006062226, WO2006052457, WO2005104264, WO2005056633, WO2005033174, WO2004113412, WO2004041901, WO2003099901, WO2003051092, WO2003020790, WO2003020790, US2020040076853, US2020040002576, US2007208567, US2005962631, EP201345477, EP2001344788 and DE102004020298, the entire contents of which are incorporated herein by reference.

In another embodiment, the polymers suitable for the present disclosure are non-conjugated polymers. The non-conjugated polymer can be a backbone with all functional groups at side chains. Some of the non-conjugated polymers used as phosphorescent hosts or phosphorescent light-emitting materials are disclosed in the patent applications, such as, U.S. Pat. No. 7,250,226 B2, JP2007059939A, JP2007211243A2 and JP2007197574A2. Some of non-conjugated polymers used as a fluorescent light-emitting material are disclosed in the patent applications, such as, JP2005108556, JP2005285661 and JP2003338375. Further, the non-conjugated polymer can also be a polymer, in which conjugated functional units at the backbone are linked by non-conjugated link units. Examples of such polymers are disclosed in DE102009023154.4 and DE102009023156.0. The entire contents of the above patent documents are incorporated herein by reference.

The present disclosure further relates to a method for preparing film containing a functional material by printing or coating and the method includes a step of printing or coating any one of the above formulations on a substrate, where the printing or coating method is selected from (but are not limited to) ink-jet printing, nozzle printing, typographic printing, screenprinting, dip coating, spin coating, blade coating, roller printing, torsion roller printing, lithographic printing, flexographic printing, rotary printing, spray coating, brush coating or pad printing, slot die coating and so on.

In one embodiment, the film containing the functional material is prepared by ink-jet printing. Ink-jet printers for printing the ink of the present disclosure have been commercialized and have drop-on-demand print-heads. These printers are commercially available from Fujifilm Dimatix (Lebanon, N.H.), Trident International (Brookfield, Conn.), Epson (Torrance, Calif.), Hitachi Data systems Corporation (Santa Clara, Calif.), Xaar PLC (Cambridge, United Kingdom) and Idanit Technologies, Limited (Rishon Le Zion, Isreal). For example, Dimatix Materials Printer DMP-3000 (Fujifilm) can be used for printing in the present disclosure.

The present disclosure further relates to an electronic device having one or more layers of functional film and at least one of the layers of functional film is prepared from the printing ink formulation of the present disclosure, especially by a printing or coating method.

Suitable electronic devices include but are not limited to a quantum dot light-emitting diode (QLED), a quantum dot photovoltaic cell (QPV), a quantum dot light-emitting electrochemical cell (QLEEC), a quantum dot field effect transistor (QFET), a quantum dot light-emitting field effect transistor, a quantum dot laser, a quantum dot sensor, an organic light-emitting diode (OLED), an organic photovoltaic cell (OPV), an organic light-emitting electrochemical cell (OLEEC), an organic field effect transistor (OFET), an organic light-emitting field effect transistor, an organic laser, and an organic sensor.

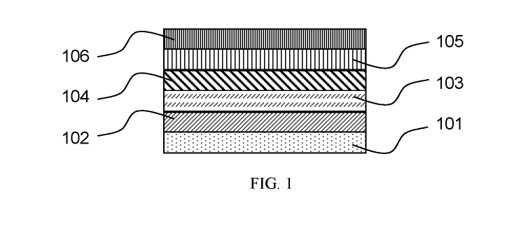

In one embodiment, the above electronic device is an electroluminescence device or a photovoltaic cell. As shown in FIG. 1, the electronic device comprises a substrate 101, an anode 102, at least one light-emitting layer or light-absorbing layer 104 and a cathode 106. Following description will be made only for the electroluminescence device.

The substrate 101 can be opaque or transparent. One transparent substrate can be used to manufacture a transparent light-emitting device. for example, referring to Bulovic, et. al, Nature 1996, 380, p 29, and Gu, et. al, Appl. Phys. Lett. 1996, 68, p 2606. The substrate can be rigid or flexible and can be selected from plastic, metal, semiconductor wafer, or glass. In one embodiment, the substrate has a smooth surface. In one embodiment, the substrate has a defect-free surface. In one embodiment, the substrate can be selected from polymer film or plastic, the glass transition temperature Tg of which is 150° C. or above, in one embodiment, above 200° C., in another embodiment, above 250° C., and in yet another embodiment, above 300° C. Suitable examples of the substrate include poly(ethylene terephthalate) (PET) and poly(ethylene-2,6-naphthalate) (PEN).

The anode 102 can contain a conducting metal or a metal oxide, or a conducting polymer. It is easy to inject holes from the anode into HIL or HTL or a light-emitting layer. In one embodiment, the absolute value of difference between the work function of the anode and the HOMO energy level or valence band energy level of the p-type semiconductor material as HIL or HTL is smaller than 0.5 eV, in one embodiment, smaller than 0.3 eV and in another embodiment, smaller than 0.2 eV. Examples of anode materials include but are not limited to, Al, Cu, Au, Ag, Mg, Fe, Co, Ni, Mn, Pd, Pt, ITO, aluminium-doped zinc oxide (AZO). Other suitable anode materials are known and can be readily selected and used by those skilled in the art. Any suitable technology can be applied to deposit the anode materials, such as, suitable PVD methods, including RF magnetron sputtering, vacuum thermal evaporation, and electron-beam (e-beam).

In some embodiments, the anode has a patterned structure. Patterned ITO conductive substrates are commercially available and can be used to prepare the device of the present disclosure.

The cathode 106 can contain a conducting metal or a metal oxide. It is easy to inject electrons from the cathode to EIL or ETL or directly to the light-emitting layer. In one embodiment, the absolute value of difference between the work function of the cathode and LUMO energy level or conduction band energy level of the n-type semiconductor material as EIL or ETL or HBL is less than 0.5 eV, in one embodiment, smaller less than 0.3 eV and in another embodiment, smaller less than 0.2 eV. In principle, all materials which can be used as the cathode of OLED can be used as the cathode material of the device of the present disclosure. Examples of the cathode materials include but are not limited to, Al, Au, Ag, Ca, Ba, Mg, LiF/Al, MgAg alloy, BaF₂/Al, Cu, Fe, Co, Ni, Mn, Pd, Pt, and ITO. Any suitable technology can be applied to the cathode materials, such as, suitable PVD methods, including RF magnetron sputtering, vacuum thermal evaporation and e-beam.

The light-emitting layer 104 at least contains a luminescent functional material, the thickness of which can be ranged from 2 nm to 200 nm. In one embodiment, the light-emitting layer in the light-emitting device of the present disclosure is prepared by printing the printing ink of the present disclosure and the printing ink comprises at least one of the above light-emitting functional materials, particularly a quantum dot material or an organic functional material.

In one embodiment, the light-emitting device of the present disclosure further comprises a hole-injection layer (HIL) or hole-transport layer (HTL) 103, such as, the above organic HTM or p-type inorganic material. In one embodiment, HIL or HTL can be prepared by printing the printing ink of the present disclosure and the printing ink comprises a functional material having hole-transport ability, particularly a quantum dot material or an organic HTM material.

In another embodiment, the light-emitting device of the present disclosure further comprises an electron-injection layer (EIL) or an electron-transport layer (ETL) 105, such as, the above organic ETM or n-type inorganic material. In some embodiments, EIL or ETL can be prepared by printing printing ink of the present disclosure and the printing ink comprises a functional material having electron-transport ability, particularly a quantum dot material or an organic ETM material.

The present disclosure further relates to the use of the light-emitting device of the present disclosure in various situations, including but not limited to, various display devices, backlight and lighting sources.

The present disclosure will be described below with reference to the embodiments, but the present disclosure is not limited to the following embodiments. It should be understood that the appended claims outline the scope of the present disclosure. Guided by the concept of the present disclosure, those skilled in the art would be appreciated that certain modification made to the various embodiments of the present disclosure will be covered by the spirit and scope of the claims of the present disclosure.

### EXAMPLES

### Example 1: Preparation of Blue Luminescent Quantum Dot (CdZnS/ZnS)

Solution 1 is prepared for use by adding 0.0512 g of S and 2.4 mL of ODE in a 25 mL one-necked flask and heating to 80° C. in an oil bath to dissolve S. Solution 2 is prepared for use by adding 0.1280 g of S and 5 mL of OA in a 25 mL one-necked flask and heating to 90° C. in an oil bath to dissolve S. Then 0.1028 g of CdO and 1.4680 g of zinc acetate and 5.6 mL of OA are added in a 50 mL three-necked flask. Subsequently, the three-necked flask is placed in a 150 mL heating jacket, wherein the necks at both sides are sealed by rubber stoppers, a condenser tube is connected above the flask and further connected to a double manifold. The three-necked flask is heated to 150° C., vacuumized for 40 min, and then introduced with nitrogen. Then, 12 mL of ODE is injected into the three-necked flask by an injector and when the temperature is raised to 310° C., 1.92 mL of Solution 1 is injected quickly into the three-necked flask by an injector. At 12 min after the injection of Solution 1, 4 mL of Solution 2 is dropwise added to the three-necked flask by an injector at a speed of about 0.5 mL/min. Reaction lasts for 3 h and when the reaction is stopped, the three-necked flask is placed in water immediately to be cooled to 150° C.

An excessive amount of n-hexane is added to the three-necked flask. The liquid in the three-necked flask is transferred to a plurality of 10 mL centrifuge tubes and subsequently treated for three times by performing centrifugation and removing the lower precipitate. Acetone is added into the liquid treated until precipitate forms. The precipitate is obtained by centrifugation and removal of supernatant liquid. Then the precipitate is dissolved with n-hexane again, acetone is added until precipitate forms, and the precipitate is obtained by centrifuging and removing supernatant liquid, and the above steps are repeated for three times. The final precipitate is dissolved with toluene and transferred to a glass vessel for storage.

### Example 2: Preparation of Green Luminescent Quantum Dot (CdZnSeS/ZnS)

Solution 1 is prepared for use by adding 0.0079 g of Se and 0.1122 g of S in a one-necked flask, adding 2 mL of TOP, introducing nitrogen gas and stirring. Then 0.0128 g of CdO, 0.3670 g of zinc acetate and 2.5 mL of OA are added to a 25 mL three-necked flask. The necks of the flask at both sides are sealed by rubber stoppers, a condenser tube is connected above the flask and further connected to a double manifold. The three-necked flask is subsequently placed in a 50 mL heating jacket, vacuumized, introduced with nitrogen gas, heated to 150° C. and vacuumized for 30 min. 7.5 mL of ODE is injected into the flask. Then the flask is heated to 300° C. and 1 mL of Solution 1 is injected quickly. At 10 min after injection of Solution 1, the reaction is immediately stopped, and the three-necked flask is placed in water to cool down.

5 mL of n-hexane is added to the three-necked flask to obtain a mixed liquid. The mixed liquid is transferred to a plurality of 10 mL centrifuge tubes and added with acetone until precipitate forms. After centrifugation and removal of the supernatant liquid, the resulting precipitate is dissolved with n-hexane and then added with acetone until precipitate forms, then centrifugation is performed, and the above steps are repeated for three times. The final precipitate is dissolved with a small amount of toluene and transferred to a glass vessel for storage.

### Example 3: Preparation of Red Luminescent Quantum Dot (CdSe/CdS/ZnS)

Cd(OA)₂ precursor is prepared by adding 1 mmol of CdO, 4 mmol of OA and 20 ml of ODE to a 100 mL three-necked flask. The three-necked flask is introduced with nitrogen and heated to 300° C. At this temperature, 0.25 mL of TOP in which 0.25 mmol of Se powders is dissolved is injected quickly. The reaction solution reacts at this temperature for 90 sec to grow a CdSe core of about 3.5 nm. The reaction solution is added dropwise with 0.75 mmol of octanethiol at 300° C. and reacts for 30 min to grow a CdS shell with a thickness of about 1 nm. Then 2 mL of TBP in which 4 mmol of S powders are dissolved and 4 mmol of Zn(OA)₂ were added dropwise to the reaction solution to grow a ZnS shell (of about 1 nm). After reacting for 10 min, the reaction solution is cooled to room temperature.

5 mL of n-hexane is added to the three-necked flask to obtain a mixed liquid. The mixed liquid is transferred to a plurality of 10 mL centrifuge tubes and added with acetone until precipitate forms. After centrifugation and removal of the supernatant liquid, the precipitate obtained is dissolved with n-hexane and then added with acetone until precipitate forms, then centrifugation is performed, and the above steps are repeated for three times. The final precipitate is dissolved with a small amount of toluene and transferred to a glass vessel for storage.

### Example 4: Preparation of ZnO Nanoparticles

Solution 1 is prepared by adding 1.475 g of zinc acetate in 62.5 mL of methanol. Solution 2 is prepared by dissolving 0.74 g of KOH in 32.5 mL of methanol. Solution 1 is heated to 60° C. and stirred vigorously. Solution 2 is added dropwise to Solution 1 by a sample injector to obtain a mixed solution system. The mixed solution system is stirred at 60° C. for further 2 h. The heating source is removed and the solution system is allowed to stand for 2 h. The reaction solution is centrifuged at 4500 rpm for 5 min and washed for at least three times. The final white solid obtained is ZnO nanoparticles having a diameter of about 3 nm.

### Example 5: Preparation of Printing Ink Comprising 2,4-Dimethylsulfolane and Quantum Dots

An agitator and a vial are cleaned and transferred to a glove box with the agitator placed in the vial. 9.5 g of 2,4-dimethylsulfolane is added in the vial. Quantum dots solids are obtained by being precipitated from the above solution into acetone and centrifuged. 0.5 g of the quantum dots solids is weighed in the glove box and added to the solvent system in the vial and stirred at 60° C. until being completely dispersed, and a resulting solution is cooled to room temperature. The resulting solution of quantum dots is filtered by a PTFE membrane of 0.2 μm, and then sealed and stored.

### Example 6: Preparation of Printing Ink Comprising ZnO Nanoparticles and Diethylenetriamine

An agitator and a vial are cleaned and transferred to a glove box with the agitator placed in the vial. 9.5 g of diethylenetriamine is added in the vial. 0.5 g of ZnO nanoparticles is weighed in the glove box and added to the solvent system in the vial and stirred and mixed at 60° C. until being completely dispersed to obtain a solution. The resulting solution is cooled to room temperature. The resulting solution of ZnO nanoparticles is filtered by a PTFE membrane of 0.2 μm, and then sealed and stored.

The organic functional materials involved in the examples below are each commercially available, for example, from Jilin OLED Material Tech Co., Ltd, www.jl-oled.com, or prepared according to a method reported in documents.

### Example 7: Preparation of Printing Ink Comprising Organic Light-Emitting Layer Material and Sulfolane

In this example, the light-emitting layer organic functional material comprises a phosphorescent host material and a phosphorescent emitter material.

The phosphorescent host material is selected from following carbazole derivatives:

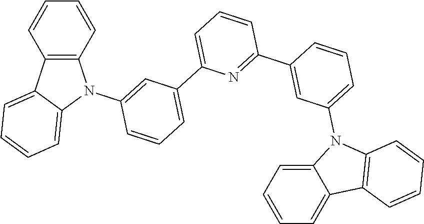 [SMILES: c1cc(-c2cccc(-c3cccc(-n4c5ccccc5c5ccccc54)c3)n2)cc(-n2c3ccccc3c3ccccc32)c1]

The phosphorescent emitter material is selected from following Ir complexes:

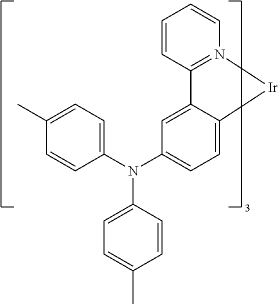

An agitator and a vial are cleaned and transferred to a glove box with the agitator placed in the vial. 9.8 g of sulfolane is added in the vial. 0.18 g of a phosphorescent host material and 0.02 g of a phosphorescent emitter material are weighed in the glove box and added to the solvent system in the vial and stirred and mixed at 60° C. until the organic functional material is completely dissolved to obtain a solution. The resulting solution is cooled to room temperature. The resulting solution of the organic functional material is filtered by a PTFE membrane of 0.2 μm, and then sealed and stored.

### Example 8: Preparation of Printing Ink Comprising Organic Light-Emitting Layer Material and m-Toluidine

In this example, the light-emitting layer organic functional material comprises a fluorescent host material and a fluorescence emitter material.

The fluorescent host material is selected from following spirofluorene derivatives:

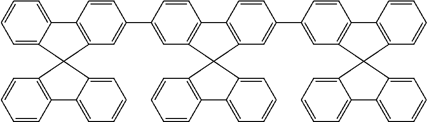 [SMILES: c1ccc2c(c1)-c1ccccc1C21c2ccccc2-c2ccc(-c3ccc4c(c3)C3(c5ccccc5-c5ccccc53)c3cc(-c5ccc6c(c5)C5(c7ccccc7-c7ccccc75)c5ccccc5-6)ccc3-4)cc21]

The fluorescence emitter material is selected from following compounds:

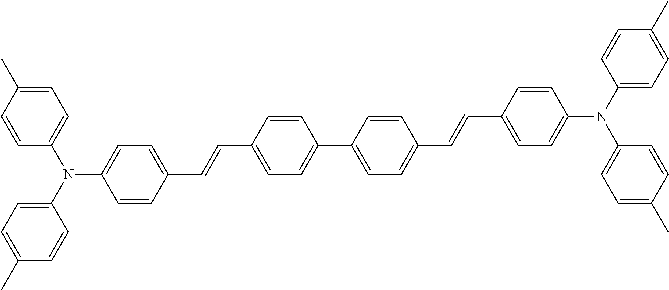 [SMILES: Cc1ccc(N(c2ccc(C)cc2)c2ccc(/C=C/c3ccc(-c4ccc(/C=C/c5ccc(N(c6ccc(C)cc6)c6ccc(C)cc6)cc5)cc4)cc3)cc2)cc1]

An agitator and a vial are cleaned and transferred to a glove box with the agitator placed in the vial. 9.8 g of m-toluidine is added in the vial. 0.19 g of a phosphorescent host material and 0.01 g of a phosphorescent emitter material are weighed in the glove box and added to the solvent system in the vial and stirred and mixed at 60° C. until the organic functional material is completely dissolved to obtain a solution. The resulting solution is cooled to room temperature. The resulting solution of the organic functional material is filtered by a PTFE membrane of 0.2 μm, and then sealed and stored.

### Example 9: Preparation of Printing Ink Comprising Organic Light-Emitting Layer Material and Aniline

In this example, the light-emitting layer organic functional material comprises a host material and a TADF material.

The host material is selected from the compounds having the following structure:

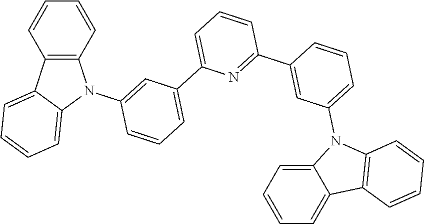 [SMILES: c1cc(-c2cccc(-c3cccc(-n4c5ccccc5c5ccccc54)c3)n2)cc(-n2c3ccccc3c3ccccc32)c1]

The TADF material is selected from the compounds having the following structure:

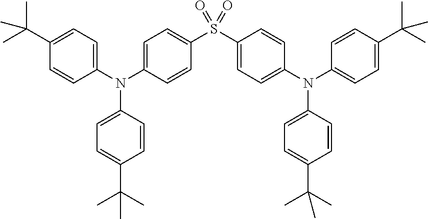 [SMILES: CC(C)(C)c1ccc(N(c2ccc(C(C)(C)C)cc2)c2ccc(S(=O)(=O)c3ccc(N(c4ccc(C(C)(C)C)cc4)c4ccc(C(C)(C)C)cc4)cc3)cc2)cc1]

An agitator and a vial are cleaned and transferred to a glove box with the agitator placed in the vial. 9.8 g of aniline is added in the vial. 0.19 g of a host material of and 0.01 g of a TADF material are weighed in the glove box and added to the solvent system in the vial and stirred and mixed at 60° C. until the organic functional material is completely dissolved to obtain a solution. The resulting solution is cooled to room temperature. The resulting solution of the organic functional material is filtered by a PTFE membrane of 0.2 μm, and then sealed and stored.

### Example 10: Preparation of Printing Ink Comprising Hole-Transport Material and N,N-Dibutylaniline

In this example, the printing ink comprises a hole-transport layer material having hole-transport ability.

The hole-transport material is selected from following triarylamine derivatives:

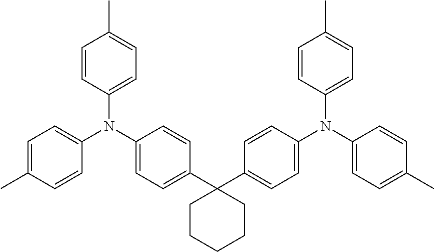

An agitator and a vial are cleaned and transferred to a glove box with the agitator placed in the vial. 9.8 g of N,N-dibutylaniline is added in the vial. 0.2 g of a hole-transport material is weighed in the glove box and added to the solvent system in the vial and stirred and mixed at 60° C. until the organic functional material is completely dissolved to obtain a solution. The resulting solution is cooled to room temperature. The resulting solution of the organic functional material is filtered by a PTFE membrane of 0.2 μm, and then sealed and stored.

### Example 11: Viscosity and Surface Tension Tests

A viscosity of the ink comprising a functional material is tested by a DV-I Prime Brookfield rheometer. A surface tension of the ink comprising a functional material is tested by a SITA bubble pressure tensiometer.

According to the above tests, the viscosity of the ink comprising the functional material obtained in Example 5 is 8.6±0.5 cPs and the surface tension is 27.8±0.5 dyne/cm.

According to the above tests, the viscosity of the ink comprising the functional material obtained in Example 6 is 7.7±0.5 cPs and the surface tension is 37.2±0.3 dyne/cm.

According to the above tests, the viscosity of the ink comprising the functional material obtained in Example 7 is 10.5±0.5 cPs and the surface tension is 33.1±0.5 dyne/cm.

According to the above tests, the viscosity of the ink comprising the functional material obtained in Example 8 is 5.4±0.5 cPs and the surface tension is 35.1±0.3 dyne/cm.

According to the above tests, the viscosity of the ink comprising the functional material obtained in Example 9 is 5.1±0.5 cPs and the surface tension is 37.8±0.1 dyne/cm.

According to the above tests, the viscosity of the ink comprising the functional material obtained in Example 10 is 7.8+0.5 cPs and the surface tension is 31.8+0.3 dyne/cm.

The printing inks comprising functional materials formulated above can be used to prepare functional layers of light-emitting diodes (such as, a light-emitting layer and an electron-transport layer) by ink-jet printing. Specific steps thereof are as follows:

an ink comprising a functional material is filled in an ink bucket provided in an ink-jet printer, such as, Dimatix Materials Printer DMP-3000 (Fujifilm). The wave, pulse time and voltage for jetting ink are adjusted to optimize the jetting of ink and stabilize a jetting range of ink. By way of example, an OLED/QLED device having a functional material film as a light-emitting layer thereof is prepared according to the technical solution below: adopting a glass having a thickness of 0.7 mm and sputtered with ITO electrode patterns as a substrate of OLED/QLED; patterning a pixel defining layer on ITO to obtain holes for depositing the printing ink therein; ink-jet printing a HIL/HTL material into the holes and drying at high temperature under vacuum to remove the solvent to obtain HIL/HTL film; afterwards, ink-jet printing a printing ink comprising a light-emitting functional material to the HIL/HTL film and drying at high temperature under vacuum to remove the solvent to form light-emitting layer film; subsequently, ink-jet printing a printing ink comprising a functional material having electron-transport ability onto the ligh-emitting layer film and drying at high temperature under vacuum to remove the solvent to form an electron-transport layer (ETL), or alternatively, performing vacuum thermal evaporation on an organic electron-transport material to form the ETL, then forming an A1 cathode by vacuum thermal evaporation, and finally, encapsulating to complete preparation of an OLED/QLED device.

The technical features of the above-described embodiments can be arbitrarily combined. For simplicity, not all possible combinations of the technical features in the above embodiments are described. However, the combinations shall fall into the scope of the present disclosure as long as there is no contradiction among the combinations of these technical features.

What described above are several embodiments of the present disclosure, and they are specific and detailed, but not intended to limit the scope of the present disclosure. It would be understood by those skilled in the art that various modifications and improvements can be made without departing from the concept of the present disclosure, and all these modifications and improvements are within the scope of the present disclosure. The scope of the present disclosure shall be subject to the claims attached.

1. A printing formulation comprising a functional material and a solvent formulation, wherein the solvent formulation is selected from one or more compounds having following general formulae: 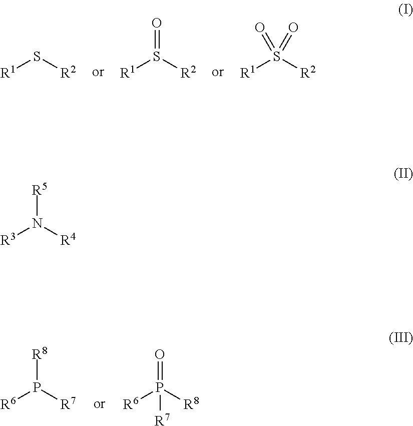
where R¹, R², R³, R⁴, R⁵, R⁶, R⁷, and R⁸ are identical or different, and are each independently selected from H and D; straight-chain alkyl, straight-chain alkoxy, or straight-chain thioalkoxy each containing 1-20 C atoms; branched or cyclic alkyl, branched or cyclic alkoxy, branched or cyclic thioalkoxy, or branched or cyclic silyl each containing 3-20 C atoms; substituted C₁-C₂₀ keto, C₂-C₂₀ alkoxycarbonyl; C₇-C₂₀ aryloxycarbonyl, cyano, carbamoyl, haloformyl, formyl, isocyano, an isocyanate group, a thiocyanate group or an isothiocyanate group, hydroxyl, nitro, a CF₃ group, Cl, Br, F; a substituted or unsubstituted 5- to 40-membered aromatic or heteroaromatic ring, or a 5- to 40-membered aryloxy or heteroaryloxy ring.

2. The printing formulation of claim 1, wherein the solvent formulation has a viscosity at 25° C. in a range from 1 cPs to 100 cPs and a boiling point of 150° C. or above.

3. The printing formulation of claim 1, wherein the solvent formulation has a surface tension at 25° C. in a range from 19 dyne/cm-50 dyne/cm.

4. The printing formulation of claim 1, wherein the functional material accounts for 0.3%-70% based on the total weight of the printing formulation and the solvent formulation accounts for 30%-99.7% based on the total weight of the printing formulation.

5. The printing formulation of claim 1, wherein the solvent formulation is selected from the group consisting of diphenyl sulfide, tert-dodecylthiol, dimethyl sulfoxide, sulfolane, dimethylsulfone, 2,4-dimethylsulfolane, N-benzylmethylamine, triisopentylamine, dihexyl amine, trihexylamine, dioctylamine, decylamine, didecylamine, aniline, N-methylaniline, N,N-dimethylaniline, N,N-diethylaniline, N-propylaniline, N-butylaniline, N,N-dibutylaniline, N-pentylaniline, N,N-dipentylaniline, N, N-di-tert-pentylaniline, 3,5-dimethylaniline, benzylamine, o-toluidine, m-toluidine, p-toluidine, 4-tert-pentylaniline, N,N-diethylbenzylamine, N,N-diethylcyclohexylamine, diethylenetriamine, triethylenetetramine, formamide, N-methylformamide, acetamide, N-methylacetamide, 2-pyrollidinone, N-methylpyrollidinone, trihexylphosphine, trioctylphosphine, trimethyl phosphate, triethyl phosphate, triphenyl phosphate, diethyl phosphate, and any combination thereof.

6. The printing formulation of claim 1, wherein the solvent formulation further comprises a second solvent and the second solvent is selected from the group consisting of an aromatic compound, a heteroaromatic compound, an ester compound, fatty ketone, fatty ether, and any combination thereof.

7. The printing formulation of claim 1, wherein the functional material is an inorganic nanomaterial.

8. The printing formulation of claim 7, wherein the inorganic nanomaterial is a luminescent quantum dot material having an emission wavelength from 380 nm to 2500 nm.

9. The printing formulation of claim 7, wherein the inorganic nanomaterial is a binary or multinary semiconductor compound selected from the group consisting of Group IV, II-VI, II-V, III-V, III-VI, IV-VI, I-III-VI, II-IV-VI and II-IV-V of the Periodic Table of the Elements, and any combination thereof.

10. The printing formulation of claim 9, wherein the inorganic nanomaterial is a metal nanoparticle material or a metal oxide nanoparticle material or any mixture thereof.

11. The printing formulation of claim 9, wherein the inorganic nanomaterial is a perovskite nanoparticle material.

12. The printing formulation of claim 1, wherein the functional material is an organic functional material selected from the group consisting of a hole-injection material, a hole-transport material, an electron-transport material, an electron-injection material, an electron-blocking material, a hole-blocking material, a light emitter, a host material, an organic dye, and any combination thereof.

13. A use of the printing formulation of claim 1 in preparation of an electronic device.

14. An electronic device comprising a functional film prepared from the printing formulation of claim 1.

15. The electronic device of claim 14, wherein a method for preparing the functional film comprises a step of coating or printing the printing formulation on a substrate.

16. The electronic device of claim 15, wherein the coating or printing method is selected from the group consisting of ink-jet printing, nozzle printing, typographic printing, screenprinting, dip coating, spin coating, blade coating, roller printing, torsion roller printing, lithographic printing, flexographic printing, rotary printing, spray coating, brush coating, pad printing and slot die coating.

17. The electronic device of claim 14, being selected from the group consisting of a quantum dot light-emitting diode, a quantum dot photovoltaic cell, a quantum dot light-emitting electrochemical cell, a quantum dot field effect transistor, a quantum dot light-emitting field effect transistor, a quantum dot laser, a quantum dot sensor, an organic light-emitting diode, an organic photovoltaic cell, an organic light-emitting electrochemical cell, an organic field effect transistor, an organic light-emitting field effect transistor, an organic laser and an organic sensor.
